(19) United States
(12) Patent Application Publication
(10) Pub. No.: US 2009/0067150 A1
(43) Pub. Date: Mar. 12, 2009

(54) Protection Film for Preventing Leakage of Information, Portable Pouch, Card Case, and Information-Leakage Preventing Plate

(76) Inventor: Tomoaki Ito, Osaka (JP)

Correspondence Address: WOOD, PHILLIPS, KATZ, CLARK & MORTIMER, 500 W. MADISON STREET, SUITE 3800, CHICAGO, IL, 60661, US

(21) Appl. No.: 11/886,814

(22) PCT Filed: Mar. 20, 2006
(86) PCT No.: PCT/JP2006/305542

§ 371 Date: Sep. 21, 2007

(30) Foreign Application Priority Data
Mar. 22, 2005 (JP) 2005-082159
May 13, 2005 (JP) 2005-140721
May 13, 2005 (JP) 2005-141611
Aug. 16, 2005 (JP) 2005-235695
Sep. 29, 2005 (JP) 2005-285032
Sep. 29, 2005 (JP) 2005-285071
Jan. 16, 2006 (JP) 2006-007826
Jan. 25, 2006 (JP) 2006-016894

(51) Int. Cl. G06Q 30/00; H05K 9/00

(52) U.S. Cl. 361/818; 174/388; 705/14

(57) ABSTRACT

A laminated film (protection film for preventing leakage of information) is laminated on each of base clothes of a portable pouch. The laminated film is formed by lamination of an aluminum foil layer and a resin layer. The portable pouch has the laminated film over the inner surface thereof, whereby electromagnetic wave does not leak outside. That avoids skimming.

### BACKGROUND OF THE INVENTION

1. Field of the Invention

The present invention relates to card cases or portable pouches such as a bag, a bag cargo, a wallet, a pass holder, and a card holder, especially to a portable pouch or the like onto which a function of preventing leakage of personal information is added. Simultaneously, the present invention relates to a protection film for preventing leakage of information for use in the above-mentioned pouch or the like.

Simultaneously, the present invention relates to applications of a laminated film to be used as a protection film for preventing leakage of information or an electromagnetic-wave shielding film.

2. Description of the Related Art

Portable pouches such as a bag and a card holder are known from a long time ago and used daily by everyone. Such pouches can contain not only coins or handkerchiefs but also cards such as credit cards or bank cards.

These cards include, for example, a card containing an embedded IC chip or the like as shown in the patent document 1. Such an IC chip records therein important information such as account information or personal identification numbers.

Patent Document 1: JP 2005-73113A

### SUMMARY OF THE INVENTION

### Problems to be Solved by the Invention

Recently, a fraud so-called skimming has become a concern. Skimming is the act of reading data such as account information and personal identification numbers from other people's cards so as to withdraw his/her deposit or purchase articles.

At the time of filing this application, few skimmers have been arrested and their tactics are not clear. However, cards containing embedded IC chips include non-contact IC cards, and it is said that such non-contact IC cards could be skimmed by taking advantage of crowded condition during commuting time. Specifically, such a non-contact IC card is a resin card containing embedded coil and IC chip, and thus application of a magnetic field to the coil generates induced current, resulting in reading of data in the IC chip. Therefore, only by bringing of a card reader provided with a predetermined function closer to the card, data such as account information and personal identification numbers recorded in the IC chip may be read out.

Consequently, in the case of being close to other people like in a crowded train, if a person in proximity has a card reader, there is a possibility that data such as a card account number would be skimmed. Further, recently, card readers improve in quality and card readers having substantially the same size as cards are also commercially available. On such present showing, there is rising concern about skimming, so that measures to prevent skimming have been desired.

One of the measures to prevent skimming would be performed by attaching a metal plate to a bag or a card holder so as to shield an electromagnetic wave leaking from a card therein, but a card holder or the like having such a configuration is forced to be thick, being inconvenient to carry.

That would be also performed by attaching a metal foil, but a metal foil is easily breakable and undurable, and further is difficult to be attached.

Based on the above-mentioned current situation, it is therefore an object of the present invention to provide a pouch adapted to prevent information recorded in a card or the like from being skimmed, without inconvenience to carry, with high durability, and designed for easier manufacturing. Simultaneously, it is an object to provide a film for preventing a fraud such as skimming.

Further, mobile phones are widely used as one of communication tools. A call by a mobile phone is made as follows: Sound is converted into electromagnetic wave by one's mobile phone handset and the wave is transmitted to a base station, which is connected to a base station of an addressee via a facility such as a switching equipment, and then the base station of the addressee transmits the electromagnetic wave to a mobile phone handset of the addressee. Thus, in making a call, a mobile phone handset emits electromagnetic wave, which is emitted even in a so-called standby mode.

A mobile phone is often carried in a trouser pocket or a breast pocket. As described above, a mobile phone emits electromagnetic wave even in a standby mode, resulting in a concern that exposure to electromagnetic wave could lead to suspected health problems.

When being carried in a trouser pocket, for example, a mobile phone comes close to testes or ovaries. That causes concerns that the sperm or the ovum might be killed or deformed by electromagnetic wave emitted at this time. There is also another worry that the cells producing the sperm might be killed or deformed by electromagnetic wave. Especially, there is a worry that electromagnetic wave might have a bad effect on baby in the womb for pregnant women.

Mobile phones further emit electromagnetic wave as described above and are used by directly pressing handsets onto the head, resulting in a worry about the brain damage caused by electromagnetic wave. Specifically, there is a worry that the brain might suffer from fever by electromagnetic wave or that electromagnetic wave might cause cancer.

The report by the researchers who study the effects of mobile phones on the human body shows that brain's fever while using a mobile phone, for example, is within ignorable range and would not cause health damage.

As to a cancer risk by electromagnetic wave, the World Health Organization (WHO) established the International EMF (electromagnetic fields) Project in May 1996 to assess possible health and environmental effects of exposure to electromagnetic wave. According to the EMF Project's research, carcinogenicity caused by mobile phones is denied.

Such researches show that mobile phone would not cause health damage at present.

However, mobile phones are products that have been developed recently. Thus, in fact, there is provided no data whether the long use thereof causes a health problem, so that there is provided no evidence to allege that the long use of mobile phones causes no health problem.

Further, recently, concerns that mobile phones might cause a harmful influence on a cardiac pacemaker (hereinafter referred to as only a “pacemaker”) have been expressed. The pacemaker is a medical device implanted in the body and adapted to send weak electric signals to the cardiac muscle so as to improve the cardiac rate in a condition tailored to daily life. Therefore, the pacemaker generates electric signals in a predetermined cycle.

However, when the pacemaker is exposed to a strong magnetism or electromagnetic wave, the electric signals might be transmitted in an irregular cycle or become weak.

Thus, the use of mobile phones in the vicinity of the pacemaker wearer might cause a malfunction of the pacemaker and might possibly cause the wearer to faint.

It is therefore an object of the present invention to develop clothing capable of dispelling the concerns regarding health of mobile phone users or pacemaker wearers.

Simultaneously, it is another object of the present invention to develop a mobile phone handset capable of reducing irradiance of electromagnetic wave to the brain in using the mobile phone so as to dispel the concerns regarding health of mobile phone users.

### Means to Solve the Problem

A first aspect of the present invention to solve the above-mentioned problems and drawbacks is a protection film for preventing leakage of information, including at least one metal layer and at least one resin layer laminated on each other.

By such a protection film for preventing leakage of information, a metal layer shields electromagnetic field, thereby preventing leakage of information recorded in a medium such as a card. Further, the protection film of the present aspect is also applicable to an architectural material, thereby preventing electromagnetic wave emitted out of a device such as an in-room telephone from leaking outside a room, so as to prevent leakage of information.

The metal layer may be made of a material such as aluminum, copper, and silver. However, because copper rusts easily and silver is expensive, aluminum is best suited to the material.

In view of the above-mentioned respects, in the protection film, the metal layer is preferably an aluminum layer.

The protection film may include a plurality of the metal layers.

In the protection film, the metal layers may include at least an aluminum layer.

It is recommended that the protection film includes at least one carbon layer.

A carbon layer has a function of absorbing electromagnetic wave, thereby avoiding leakage of information recorded in a medium such as a card.

The protection film preferably includes a plurality of carbon layers.

It is recommended, for example, that the carbon layers are attached to both sides of the protection film.

The protection film may have various kinds of metal layers.

The protection film preferably includes an aluminum layer and an iron layer.

An aluminum layer has a high function of shielding electromagnetic wave and an iron layer has a high function of shielding magnetism, so that lamination of the both layers brings about a greater effect.

The protection film preferably includes an aluminum layer and a silver layer.

An aluminum layer and a silver layer have different frequency ranges for effectively shielding electromagnetic wave. Therefore, lamination of the both layers complements a frequency range of low shielding effect one another.

The protection film may include a copper layer.

The protection film preferably has strength enough to be sewn.

Such the protection film is capable of being sewn, so as to be sewn onto a portion such as an inner surface of a pouch. That prevents leakage of electromagnetic wave.

A second aspect of the present invention is a portable pouch attached with any of the above-mentioned protection film for preventing leakage of information.

A portable pouch of the present aspect is attached with the film on which a layer such as an aluminum layer is laminated. The layer shields electromagnetic wave, thereby preventing leakage of information recorded in a card.

Further, the film is attached to the portable pouch, being thin, so that a total thickness of the pouch is not increased.

Still further, the pouch uses the film on which a metal such as an aluminum foil and a resin are laminated, so as to have enough strength and high durability. The film joins other members by sewing, so as not to obstruct manufacturing of the pouch.

It is preferable that the portable pouch of the present aspect is provided with a card insertion pocket adapted to hold a card with part of the card exposed outside of the pocket, the card insertion pocket being attached with the protection film.

Such a portable pouch is provided with a card insertion pocket adapted to hold a card with part of the card exposed outside of the pocket, which facilitates taking out and putting in of the card. Further, it is not necessary to cover the entire surface of the card and is enough to cover a particular part such as a coil region. Such the portable pouch has a laminated film attached to the card insertion pocket so that the particular part is covered with the laminated film, whereby electromagnetic wave does not leak outside.

It is preferable that the portable pouch of the present aspect is provided with a card insertion pocket adapted to hold a card with part of the card exposed outside of the pocket, the card insertion pocket being formed by an inner wall to face a main body of the pouch and an outer wall on the opposite side of the inner wall, and the protection film being attached to at least the inner wall of the pocket.

Herein, a term “to (at least) the inner wall” denotes a direction and is different from the “inner wall” itself. Thus, “the protection film being attached to at least the inner wall of the pocket” means that the protection film may be attached directly to the inner wall (including front, rear, and inner surfaces of the inner wall) or may be attached to a separate wall from the inner wall: that is, an outer wall of the pouch, for example. The same can be said to the following description.

Such a portable pouch is also provided with a card insertion pocket adapted to hold a card with part of the card exposed outside of the pocket, which facilitates taking out and putting in of the card. Further, the protection film is attached to the inner wall of the pocket, thereby preventing electromagnetic wave from leaking toward a main body of the pouch. Still further, since a card can be inserted into the pocket with part of the card exposed out of the pocket, it is possible to emit electromagnetic wave out of the outer wall of the pocket depending on conditions such as a structure or an inserting direction of a card or a depth of the pocket.

It is preferable that the portable pouch of the present aspect is provided with a card insertion pocket formed by a first wall and a second wall, the first wall being attached with the protection film, and the second wall being permeable to electromagnetic wave.

By such a portable pouch, electromagnetic wave is prevented from emitting through one side (the first wall), but is emitted through the other side (the second wall).

The portable pouch of the present aspect is preferably adapted to contain a card having an electromagnetic wave shielding layer at its one side.

A card employed herein emits electromagnetic wave from only one side. The above-mentioned pouch, as described above, emits electromagnetic wave through only one side (the second wall). Thus, when the card is inserted into the pocket with an electromagnetic wave radiating surface of the card to face an electromagnetic wave permeable side of the pouch, a foreign reader receives electromagnetic wave radiated from the card. Conversely, when the card is inserted into the pocket with the electromagnetic wave radiating surface to face the protection film of the pouch, information recorded in the card is prevented from being read out. That avoids skimming.

It is preferable that the portable pouch of the present aspect includes a base material layer made of one selected from cloth and leather, the protection film being sewn onto the back of the base material layer.

Such a portable pouch has a base material layer having certain durability or strength. The protection film is sewn onto the back of the base material layer. Therefore, the portable pouch of the present aspect has enough strength.

The protection film may be attached to a whole area of the pouch.

A third aspect of the present invention is a card case being made of any of the above-mentioned protection film for preventing leakage of information.

A fourth aspect of the present invention is an information-leakage preventing plate incorporating any of the above-mentioned protection film for preventing leakage of information.

A fifth aspect of the present invention is any of the above-mentioned protection film for preventing leakage of information, having an adhesion layer formed at least one side.

Such a protection film has an adhesion layer formed at one side, so as to be applied to a pouch or a pass holder in existence to take measures against skimming. Further, application to a wall of a room or the like prevents electromagnetic wave from leaking out of the room, thereby taking measures against wiretapping.

A sixth aspect of the present invention relating to a card is a card provided with an information storing medium, having a laminated barrier adapted to shield or attenuate electromagnetic wave or magnetism.

A seventh aspect of the present invention is a card provided with an information storing medium, having a laminated barrier adapted to shield or attenuate electromagnetic wave or magnetism at one of both sides of the card, the sides sandwiching a part where the storing medium is disposed.

The above-mentioned cards each have a barrier, presenting a lower sensitivity compared to normal cards. That brings about a lower risk to skimming during commuting.

Specifically, important cards such as a bank card and a credit card are carried, not naked, with inserted in a card holder, and further in a pocket or a bag.

Thus, even if a skimmer intends to bring a card reader close to the cards during commuting, the card reader cannot be brought into contact directly with the cards.

Herein, the cards of the present aspects each have the barrier so as to intentionally lower sensitivity of the card. That allows a lower risk to skimming during commuting.

Further, since the cards of the present aspects each have a lower sensitivity than that of normal cards, the cards must be brought within striking distance of a card reader when being used. However, the above-mentioned important cards such as a bank card and a credit card are usually used on nearly contact with a card reader, rendering no inconvenience for users.

The storing medium in the card may be an IC chip.

The storing medium may be a magnetic storing medium.

The barrier may be a metal layer such as an aluminum foil.

The barrier may be a laminated body including a metal layer and a resin layer.

An eighth aspect or a member to achieve the above-mentioned object is a supplementary element for a card to be attached to one side of a card provided with an information storing medium, having a function of shielding or attenuating electromagnetic wave or magnetism.

A supplementary element for a card of the present aspect is attached to a card in existence, lending itself to intentional lowering of a sensitivity of an information recording medium and to reduction of a risk of skimming.

A ninth aspect of the present invention relating to a card is a skimming preventing card, being adapted to shield electromagnetic wave or magnetism, and having a printable surface.

Such a skimming preventing card is capable of being printed on its surface, so that information such as advertising contents and a telephone number may be printed thereon.

Further, such the preventing card shields electromagnetic wave and/or magnetism, so as to prevent skimming only if the preventing card is put in a wallet or a card holder with cards such as a credit card. The effect or the function of such the preventing card is not reduced, and thus the preventing card is expected to be put in a wallet for a long period of time.

Therefore, such the skimming preventing card should be a medium having high advertising effects.

A tenth aspect of the present invention is a skimming preventing card, being adapted to shield electromagnetic wave or magnetism, and having an advertisement printed on its surface.

Such a skimming preventing card has an advertisement printed on its surface. Such the preventing card is also expected to be put in a wallet for a long period of time.

An eleventh aspect of the present invention is a method for advertising, including the steps of printing of an advertisement on a skimming preventing card adapted to shield electromagnetic wave or magnetism, and distributing of the card free of charge or with charge.

By a method for advertising of the present aspect, a skimming preventing card on which an advertisement is printed is used and distributed. A person who receives the card will put the card in a case such as a wallet for a long period of time. That achieves high advertising effects.

Such the preventing card has been developed for advertising, but may be used not for advertising.

A facial portrait of a user may be printed on the above-mentioned skimming preventing card, for example.

A twelfth aspect of the present invention is a card printer, including a card containing section, a photo shooting section, a printing section adapted to print a photo shot in the photo shooting section on a card, and a card ejecting section for ejecting the printed card, wherein the card containing section contains skimming preventing cards adapted to shield electromagnetic wave or magnetism and to be printed on their surfaces.

By the present aspect, photos such as a user's facial portrait and a photo of his/her friends, loved one, children or the like are printed on the preventing card. Carrying of the cards on a daily basis prevents skimming.

A thirteenth aspect of the present invention relating to a clothing is a clothing having a part using at least one selected from (1) a film composed of lamination of a metal layer and (2) a resin layer and electromagnetic wave shielding cloth into which metallic yarn is woven.

By a film of the present aspect, a metal layer or electromagnetic wave shielding cloth shields electromagnetic wave, thereby considerably reducing electromagnetic wave radiated to a human body.

The metal layer can be made of a material such as aluminum, copper, and silver. However, because copper rusts easily and silver is expensive, aluminum is best suited to the material.

In view of the above-mentioned respects, in the clothing of the present aspect, the metal layer is preferably an aluminum foil layer.

In the clothing of the present aspect, the film preferably has a plurality of metal layers.

In the clothing of the present aspect, at least one of the metal layers is preferably an aluminum layer.

In the clothing of the present aspect, it is recommended that the film has at least one carbon layer.

A carbon layer has a function of absorbing electromagnetic wave, thereby considerably reducing electromagnetic wave radiated to a human body.

More preferably, the film has a plurality of carbon layers.

It is recommended, for example, that the carbon layers are attached to both sides of the protection film.

In the clothing of the present aspect, the film preferably has various kinds of metal layers.

Further, the film may include an aluminum layer and an iron layer.

An aluminum layer has a high function of shielding electromagnetic wave and an iron layer has a high function of shielding magnetism, so that lamination of the both layers brings about a greater effect.

The film may include an aluminum layer and a silver layer.

An aluminum layer and a silver layer have different frequency ranges for effectively shielding electromagnetic wave. Therefore, lamination of the both layers complements a frequency range of low shielding effect one another.

The film may include a copper layer.

In the clothing of the present aspect, the film preferably has strength enough to be sewn.

A film employed in the clothing is capable of being sewn, so as to be directly sewn onto an inner or an outer surface of the clothing. That shields electromagnetic wave. Further, the film can be used for sewing the clothing itself.

The clothing of the present aspect may be underwear.

In the clothing of the present aspect, at least one selected from the film and the electromagnetic wave shielding cloth may be arranged at a portion corresponding to testes.

The clothing of the present aspect arranges the film or the electromagnetic wave shielding cloth at a portion corresponding to wearer's testes in the case that the wearer is male, thereby reducing electromagnetic wave radiated to the testes.

In the clothing of the present aspect, at least one selected from the film and the electromagnetic wave shielding cloth may be arranged at a portion corresponding to ovaries.

The clothing of the present aspect arranges the film or the electromagnetic wave shielding cloth at a portion corresponding to wearer's ovaries in the case that the wearer is female, thereby reducing electromagnetic wave radiated to the ovaries.

The clothing of the present aspect preferably has a lining, at least part of the lining using at least one selected from the film and the electromagnetic wave shielding cloth.

Such a clothing uses the film or the electromagnetic wave shielding cloth as a lining, so as not to detract from a design of the clothing.

The clothing of the present aspect preferably has a pocket, at least part of the pocket using at least one selected from the film and the electromagnetic wave shielding cloth.

Such a clothing arranges the film or the electromagnetic wave shielding cloth at part or an entire surface of the pocket, so that electromagnetic wave does not leak out of the pocket when a mobile phone is put in the pocket. That causes no concerns about damage of one's health.

The clothing of the present aspect preferably has a pocket, at least one selected from the film and the electromagnetic wave shielding cloth being arranged at a portion of the pocket to face a human body.

Such a clothing arranges the film or the electromagnetic wave shielding cloth at a portion of the pocket to face a human body, so that electromagnetic wave does not leak toward a human body when a mobile phone is put in the pocket. That causes no concerns about damage of one's health. Further, a structure without the film at an outer side of the pocket or a structure with the film formed not densely at an outer side of the pocket does not interfere incoming call to a mobile phone.

In the clothing of the present aspect, the metallic yarn preferably contains one selected from aluminum and silver.

According to studies by the inventor, the use of a thread containing aluminum or silver presents a high function of shielding electromagnetic wave.

In the clothing of the present aspect, it is preferable that the cloth is woven by yarn, and that the metallic yarn makes up 10 to 50% of the total number of the yarn woven into the cloth.

The more the metallic yarn is woven into the cloth, the more an electromagnetic wave shielding function is improved, but more than 50% of the metallic yarn woven into the cloth might alter its texture. Less than 10% thereof might have a lower function of shielding electromagnetic wave, resulting in insufficient effect.

In the clothing of the present aspect, at least one selected from the film and the electromagnetic field shielding cloth is preferably arranged at a portion corresponding to a position of a cardiac pacemaker.

By the clothing of the present aspect, the film or the electromagnetic field shielding cloth is arranged at a portion corresponding to a position of a cardiac pacemaker, thereby reducing electromagnetic wave to which the pacemaker is exposed. Thus, a pacemaker wearer is freed from a worry that a pacemaker might go wrong by wearing of such the clothing.

A fourteenth aspect of the present invention relating to a mobile phone is a mobile phone handset, including a package containing integration of a microphone part for catching sound and a receiving part to be in contact with one's ear, and having a metal layer arranged at least the part to be in contact with one's ear.

A mobile phone handset of the present aspect arranges a metal layer at a receiving part to be in contact with one's ear, so that the metal layer reduces electromagnetic wave. That causes no concerns about damage of one's health even with the long use of the mobile phone.

The above-mentioned metal layer may be formed by applying a metal foil onto a surface of the package of the mobile phone handset.

Alternatively, the above-mentioned metal layer may be formed by spraying a metal onto a surface of the package of the handset.

Further alternatively, the metal layer may be formed by depositing a metal onto a surface of the package of the handset.

The above-mentioned metal layer is preferably an aluminum layer.

The above-mentioned metal layer preferably has a thickness of 8 micrometer or more.

It is recommended that the handset has a plurality of the metal layers.

The handset employed in the present aspect is preferably foldable, so that the receiving part is inwardly folded when carried.

The handset generally has a display, and the metal layer may be arranged over an entire surface of the package except the display.

Further, in the handset having an antenna projecting from the surface of the package, it is preferable that the metal layer is not arranged at part of or a front part of the antenna.

### ADVANTAGEOUS EFFECT OF THE INVENTION

The protection film for preventing leakage of information of the present invention has such an advantageous effect as adding a function of preventing leakage of information thereto. Further, the pouch of the present invention shields electromagnetic wave and/or magnetism, thereby preventing stealage of information by skimming.

The card and the supplementary element for a card of one aspect of the present invention are provided with an element for shielding or attenuating electromagnetic wave and/or magnetism, thereby preventing stealage of information by skimming.

The skimming preventing card of another aspect of the present invention shields electromagnetic wave and/or magnetism, thereby preventing stealage of information by skimming. Further, the skimming preventing card of the present invention is expected to be carried for a long time, being effective as an advertising medium.

The clothing of the present invention shields electromagnetic wave and/or magnetism so as to have an effect of avoiding damage of a wearer's health, which might otherwise be caused by electromagnetic wave. Further, wearing of the clothing of the present invention prevents malfunction of a pacemaker.

The mobile phone handset of the present invention has a metal layer attached to a side to be in contact with one's ear when in use, the metal layer reducing electromagnetic wave. Therefore, the handset avoids damage of the user's health, which might otherwise be caused by electromagnetic wave, even with long use of the mobile phone.

### BRIEF DESCRIPTION OF THE DRAWINGS

FIG. 1 is a front view of a portable pouch of a first embodiment of the present invention;

FIG. 2 is an enlarged cross sectional view taken along a line A-A in FIG. 1;

FIG. 3 is an enlarged cross sectional view of a laminated film (protection film for preventing leakage of information);

FIG. 4 is a front view of a handbag or a purse of a second embodiment of the present invention;

FIG. 5 is a front view of an inner pocket of the handbag in FIG. 4;

FIG. 6 is a perspective view showing the inner pocket in FIG. 5 with a card being inserted thereinto;

FIG. 7 is a cross sectional view of the inner pocket in FIG. 5;

FIG. 8 is a perspective view of a pass holder of a third embodiment of the present invention;

FIG. 9 is a front view showing the pass holder in FIG. 8 in an opened condition;

FIG. 10 is a perspective view of a wallet of a fourth embodiment of the present invention;

FIG. 11 is a perspective view of the wallet in FIG. 10 in an opened condition;

FIGS. 12A and 12B are views of a card of a fifth embodiment of the present invention desirable to be inserted into the wallet in FIG. 10, FIG. 12A being a view of a front face of the card, and FIG. 12B being a view of a back face of the card;

FIG. 13 is a cross sectional view of the card in FIG. 12;

FIG. 14 is a perspective view of the wallet in FIG. 10 in which the card is inserted;

FIGS. 15A and 15B each are a cross sectional view of a pocket of the wallet in FIG. 10 in which the card is inserted;

FIGS. 16A and 16B each are a perspective view of the pocket of the wallet in FIG. 10 in which the card is inserted;

FIG. 17 is a front view of a modified embodiment of the pass holder in an opened condition;

FIG. 18 is a cross sectional view of a pocket of another modified embodiment of the pass holder in which the card is inserted;

FIG. 19 is an enlarged cross sectional view of a protection film for preventing leakage of information to be stuck on a wall;

FIG. 20 is a perspective view of the protection film in FIG. 19 in being stuck on a wall;

FIG. 21 is a perspective view of a card case made by a protection film for preventing leakage of information of a sixth embodiment of the present invention;

FIG. 22 is an enlarged cross sectional view of a modified embodiment of the laminated film (protection film for preventing leakage of information);

FIG. 23 is an enlarged cross sectional view of another modified embodiment of the laminated film (protection film for preventing leakage of information);

FIG. 24 is an enlarged cross sectional view of still another modified embodiment of the laminated film (protection film for preventing leakage of information);

FIG. 25 is an enlarged cross sectional view of yet another modified embodiment of the laminated film (protection film for preventing leakage of information);

FIG. 26 is an enlarged cross sectional view of yet still another modified embodiment of the laminated film (protection film for preventing leakage of information);

FIG. 27 is an enlarged cross sectional view of a further modified embodiment of the laminated film (protection film for preventing leakage of information);

FIG. 28 is a perspective view of an information-leakage preventing plate of a seventh embodiment of the present invention;

FIG. 29 is a cross sectional view of the preventing plate in FIG. 28;

FIG. 30 is a perspective view of the preventing plate in FIG. 28 in use;

FIG. 31 is a perspective view of a modified embodiment of the card of the present invention;

FIG. 32 is a cross sectional view of the card in FIG. 31 taken along a line A-A;

FIG. 33 is a perspective view of another modified embodiment of the card of the present invention;

FIG. 34 is a cross sectional view of the card in FIG. 33 taken along a line A-A;

FIG. 35 is an enlarged cross sectional view of still another modified embodiment of the card of the present invention;

FIG. 36 is an enlarged cross sectional view of yet another modified embodiment of the card of the present invention;

FIG. 37 is an enlarged cross sectional view of yet still another modified embodiment of the card of the present invention;

FIG. 38 is a perspective view of a skimming preventing card of an eighth embodiment;

FIG. 39 is a cross sectional view of the skimming preventing card in FIG. 38;

FIG. 40 is a front view of another skimming preventing card on which an advertisement is printed;

FIG. 41 is a front view of still another skimming preventing card used as a business card;

FIG. 42 is a perspective view of a card printer used for printing a photo on a skimming preventing card;

FIG. 43 is a front view of yet another skimming preventing card on which a photo is printed;

FIG. 44 is a front view of underwear of a ninth embodiment of the present invention;

FIG. 45 is a front view of panties of a tenth embodiment of the present invention;

FIG. 46 is a front view of trousers of an eleventh embodiment of the present invention;

FIG. 47 is a schematic diagram showing inside of the trousers in FIG. 46;

FIG. 48 is a front view of a jacket of a twelfth embodiment of the present invention;

FIG. 49 is a perspective view showing a human body of a pacemaker wearer;

FIG. 50 is a perspective view of a clothing worn by the pacemaker wearer in FIG. 49;

FIG. 51 is a graph showing signals of a pacemaker supposed to be when the mobile phone is used in a vicinity of a pacemaker wearer/user;

FIG. 52 is a graph showing signals of a pacemaker supposed to be when the mobile phone is used in a vicinity of a pacemaker wearer/user wearing the clothing of the present invention;

FIGS. 53A and 53B each are a perspective view of a mobile phone handset in use, FIG. 53A being a perspective view of a mobile phone handset of the conventional art, and FIG. 53B being a perspective view of a mobile phone handset of a thirteenth embodiment of the present invention;

FIG. 54 is a perspective view of the mobile phone handset of the present invention when carried;

FIGS. 55A and 55B each are a cross sectional view of a sheet to be applied to the mobile phone handset so that a metal layer is laminated on the handset;

FIGS. 56A and 56B each are a cross sectional view of a backed sheet (i.e., a sheet including a removable paper layer) from which the sheet in FIG. 55A or 55B is made;

FIG. 57 is a schematic diagram showing procedures (a) to (c) of preliminary processing performed on a laminated sheet;

FIG. 58 is a cross sectional view showing a surface structure of a modified embodiment of the mobile phone handset of the present invention;

FIG. 59 is a perspective view of another modified embodiment of the mobile phone handset of the present invention; and

FIG. 60 is a perspective view of still another modified embodiment of the mobile phone handset of the present invention.

### DESCRIPTION OF THE PREFERRED EMBODIMENT

Now, an embodiment of the present invention will be described below in detail, making reference to the accompanying drawings.

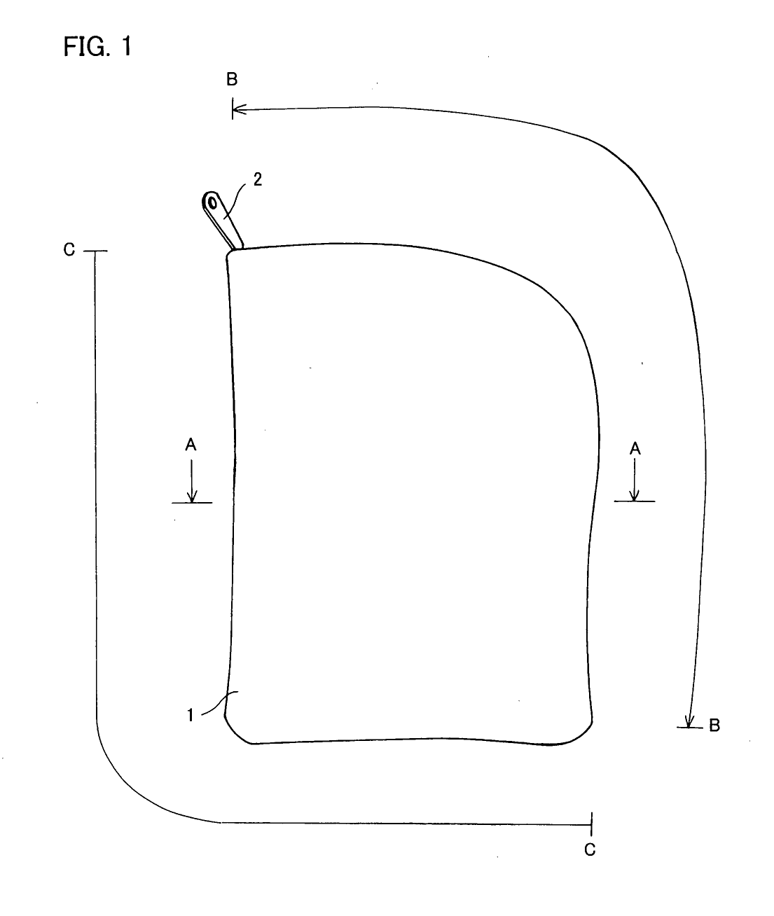

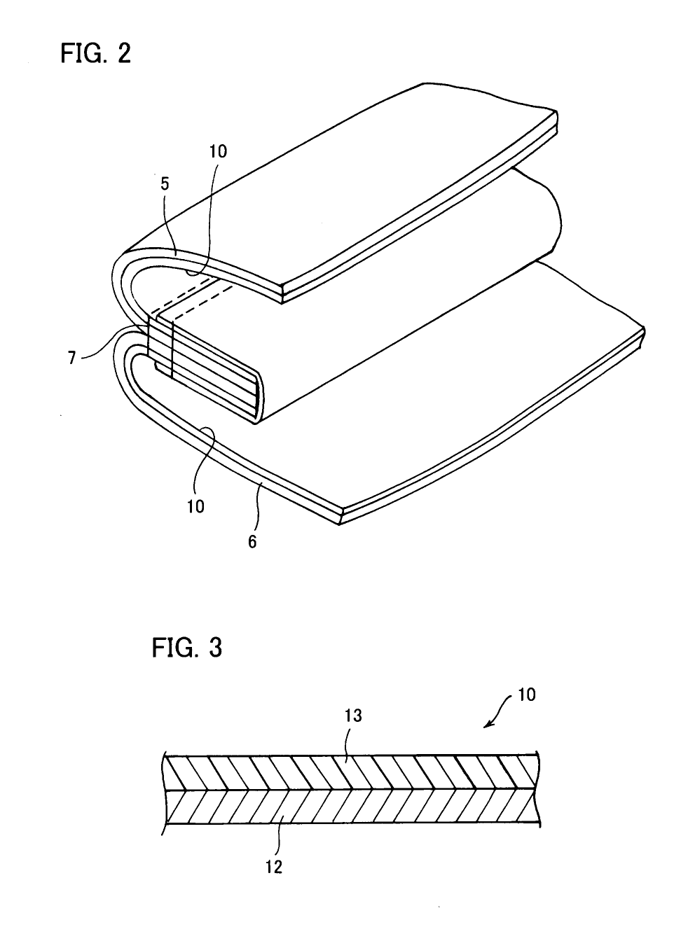

FIG. 1 is a front view of a portable pouch of a first embodiment of the present invention. FIG. 2 is an enlarged cross sectional view taken along a line A-A in FIG. 1. FIG. 3 is an enlarged cross sectional view of a laminated film (protection film for preventing leakage of information).

A portable pouch 1 shown in FIG. 1 has a substantially rectangular shape with an opening along two sides (an area B-B in FIG. 1). The opening has a zipper 2 attached thereto.

The pouch 1 is produced by sewing up the other two sides (an area C-C in FIG. 1) to be closed sides. FIG. 2 illustrates a structure of the sewn area. Specifically, the pouch 1 has a surface with an upper side made of a base cloth 5 and an under side made of another base cloth 6. The clothes 5 and 6 are lapped over each other and the edge of the lapped clothes 5 and 6 are sewn by a thread 7. The edge is stitched with another cloth, whereupon its front and back sides are reversed, so as to produce a pouch shape.

In particular, in the present embodiment, a laminated film (protection film for preventing leakage of information) 10 is laminated on each of the base clothes 5 and 6, so that the laminated film 10 is also sewn simultaneously with the clothes 5 and 6 in sewing as described above.

Consequently, the portable pouch 1 of the present embodiment has the laminated film 10 all over the inner surface thereof.

The laminated film 10 is equivalent to a material of a bag for snacks, for example, and as shown in FIG. 3, is a laminated film composed of an aluminum foil layer (aluminum deposited layer) 12 and a resin layer 13.

Herein, the aluminum foil layer 12 preferably has a thickness of 8 micrometers or more and more preferably 18 micrometers or more. That is because the aluminum foil layer 12 having a thickness less than 8 micrometers has a poor function of shielding electromagnetic wave. The aluminum foil layer 12 having a thickness of 18 micrometers or more shields electromagnetic wave having a considerable strength, thereby possessing higher reliability.

The above-mentioned laminated film 10 has a two-layer structure, but may have a structure with three layers or more. A structure having three layers or more will be described below.

The resin layer 13 may be made of any material only if it is a known resin capable of being made into a film. The material to be used includes a resin such as cellophane, polyethylene, stretched polypropylene, unstretched polypropylene, polyethylene terephthalate, polyvinylidene chloride coated biaxial stretched polypropylene, K-coat polyethylene terephthalate, ethylene-vinylalcohol copolymer.

The portable pouch 1 of the present embodiment has a space therewithin, into which an article such as a card is put with the zipper 2 opened. The pouch 1 has the laminated film 10 consisting of the aluminum foil layer 12 and the resin layer 13 all over its inner surface, thereby preventing electromagnetic wave emitted out of the card from leaking outside. That avoids skimming.

Further, the laminated film 10 is simultaneously sewed in sewing the clothes 5 and 6, so that the pouch 1 is easily produced.

In the embodiment described above, the laminated film 10 is attached to all over the inner surface of the pouch 1, but may be attached only to a main part. Specifically, the laminated film 10 is attached only to a part where a card should be placed.

Hereafter, an example in which the laminated film 10 is attached to the main part is described.

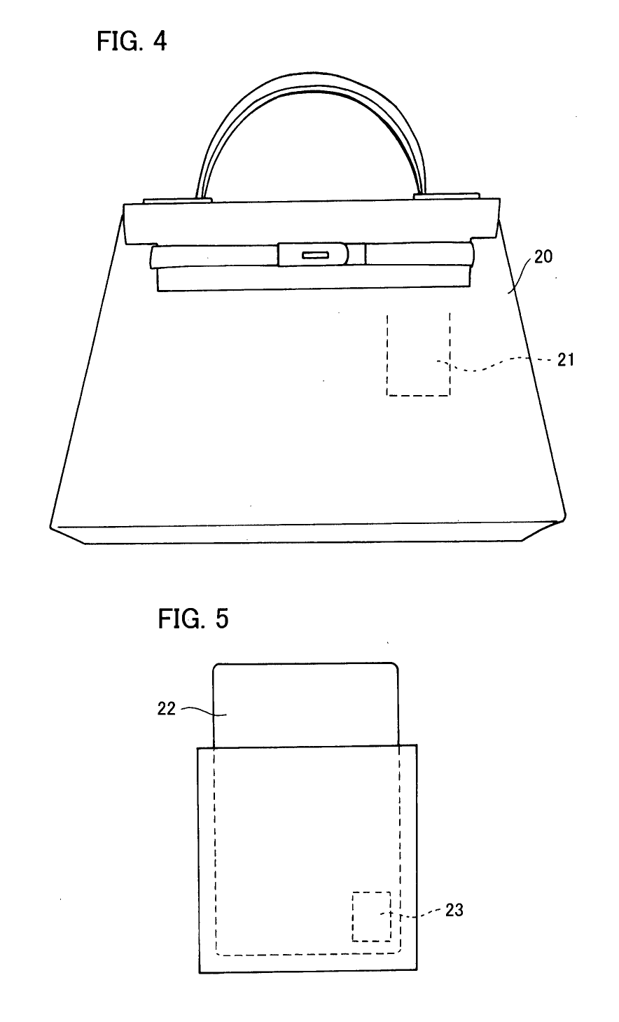

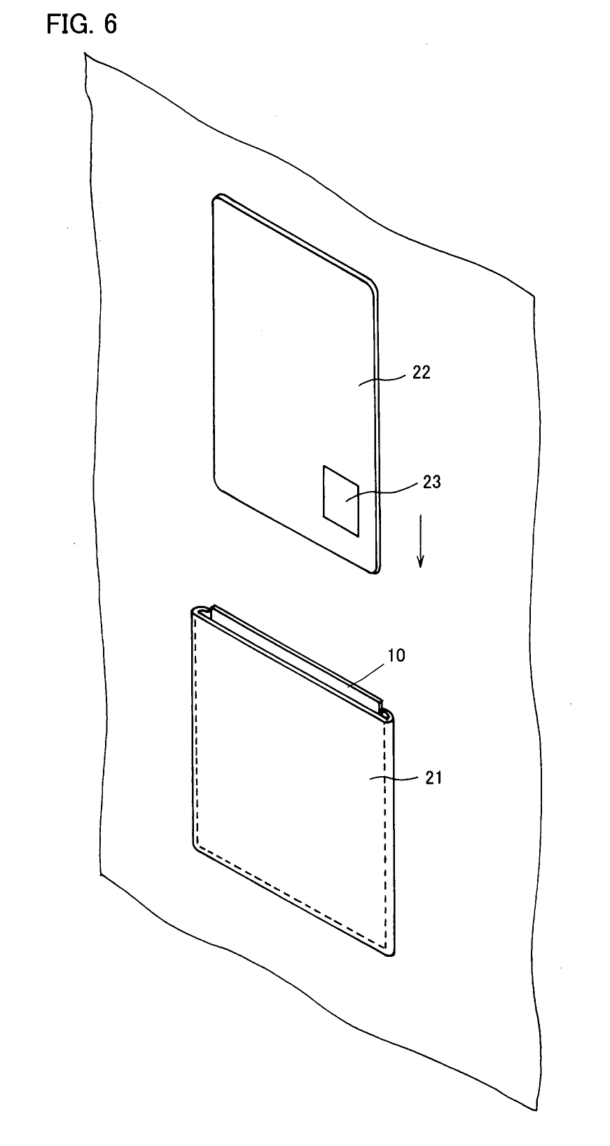

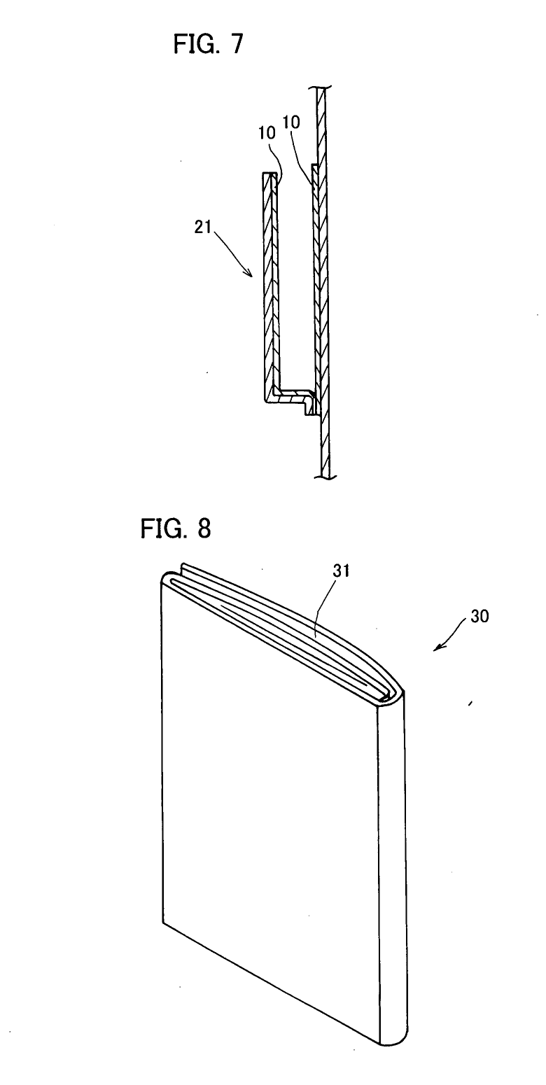

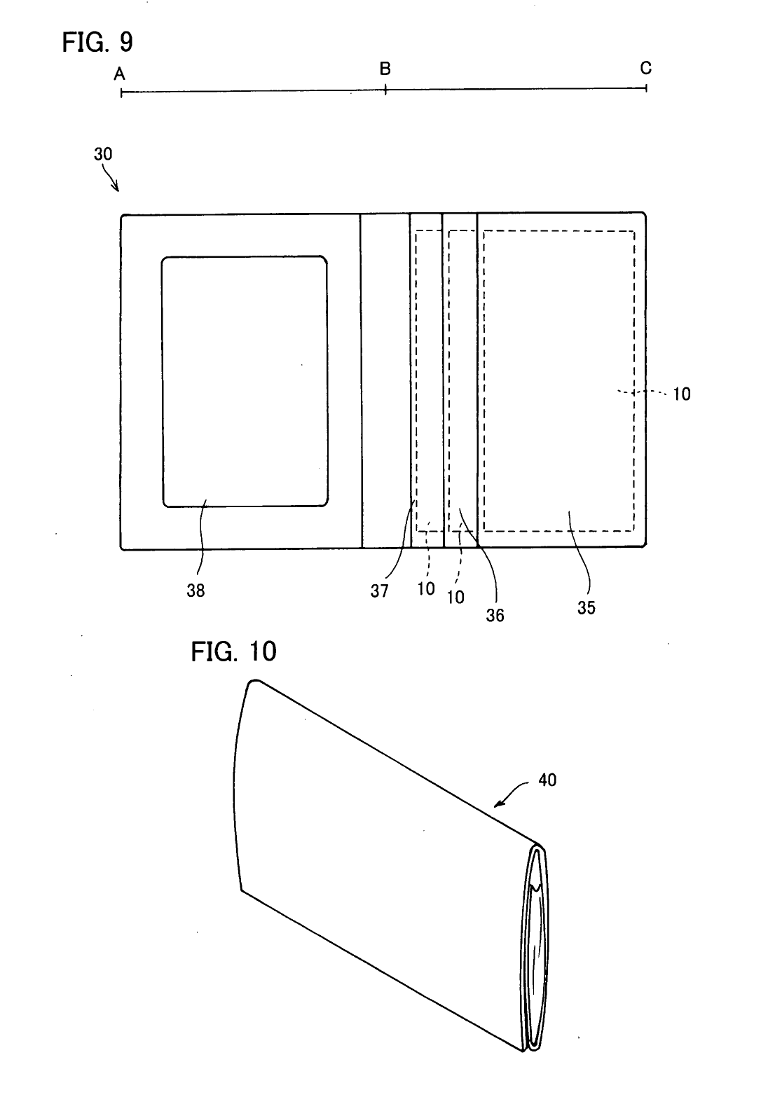

FIG. 4 is a front view of a handbag or a purse of a second embodiment of the present invention. FIG. 5 is a front view of an inner pocket of the handbag in FIG. 4. FIG. 6 is a perspective view showing the inner pocket in FIG. 5 with a card being inserted thereinto. FIG. 7 is a cross sectional view of the inner pocket in FIG. 5. FIG. 8 is a perspective view of a pass holder of a third embodiment of the present invention. FIG. 9 is a front view showing the pass holder in FIG. 8 in an opened condition.

A handbag (or a purse) 20 shown in FIG. 4 has therewithin an inner pocket (card insertion pocket) 21, into which a card 22 is generally inserted, as shown in FIG. 5. The card 22 is inserted into the inner pocket 21 such that part of the card 22 is exposed outside of the inner pocket 21, but the inner pocket 21 has a depth enough to conceal an IC chip 23 of the card 22. In the present embodiment, the above-mentioned laminated film 10 is sewn onto an inner surface of the inner pocket 21. Specifically, as shown in FIG. 7, the laminated film 10 is attached to the entire area of the inner surface of the inner pocket 21.

FIGS. 8 and 9 illustrate an example applying the present invention to a pass holder. A pass holder 30 shown in FIGS. 8 and 9 is made of leather with a twofold structure. FIG. 9 shows the pass holder 30 in an opened condition, a left side (area A-B) of the figure being a pass holder and a right side (area B-C) of the figure being a card holder.

The right side (area B-C) has three card insertion pockets 35, 36, and 37. Each of the card insertion pockets 35, 36, 37 can accommodate a card inserted therein with part of the card exposed outside of the pocket, but an IC chip 23 thereof is concealed.

The above-mentioned laminated film 10 is sewn onto an inner surface of each of the pockets 35, 36, and 37.

Into the left side (area A-B), as described above, a commutation pass is inserted. The pass holder 30 of the present embodiment has no laminated film at a pass insertion part 38 of the left side (area A-B) of the figure. Thus, electromagnetic wave emitted from the pass inserted in the part 38 comes out from the part 38. Therefore, a noncontact train pass inserted into the part 38, for example, allows a passenger to go through a ticket gate without taking out the pass every time.

As shown in FIG. 8, when being folded, the pass holder 30 defines a gap 31 between the right and left sides (card insertion side and pass insertion side), the gap 31 being slight, so that electromagnetic wave is substantially prevented from leaking. Specifically, the gap 31 is smaller than a wave length of electromagnetic wave emitted from a card, so that the electromagnetic wave is prevented from leaking. Further, a plurality of aluminum foil layers 12 are provided adjacent to the gap 31, thereby attenuating the electromagnetic wave emitted from the card.

Next, other embodiments of the present invention will be described in detail below.

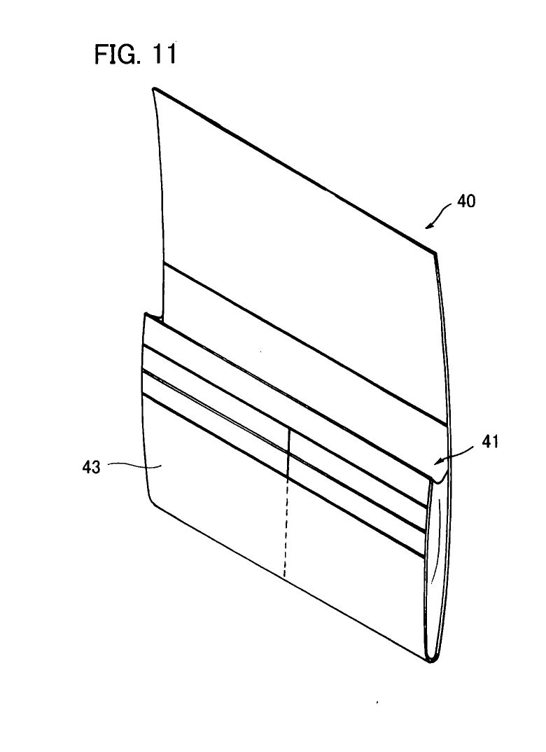

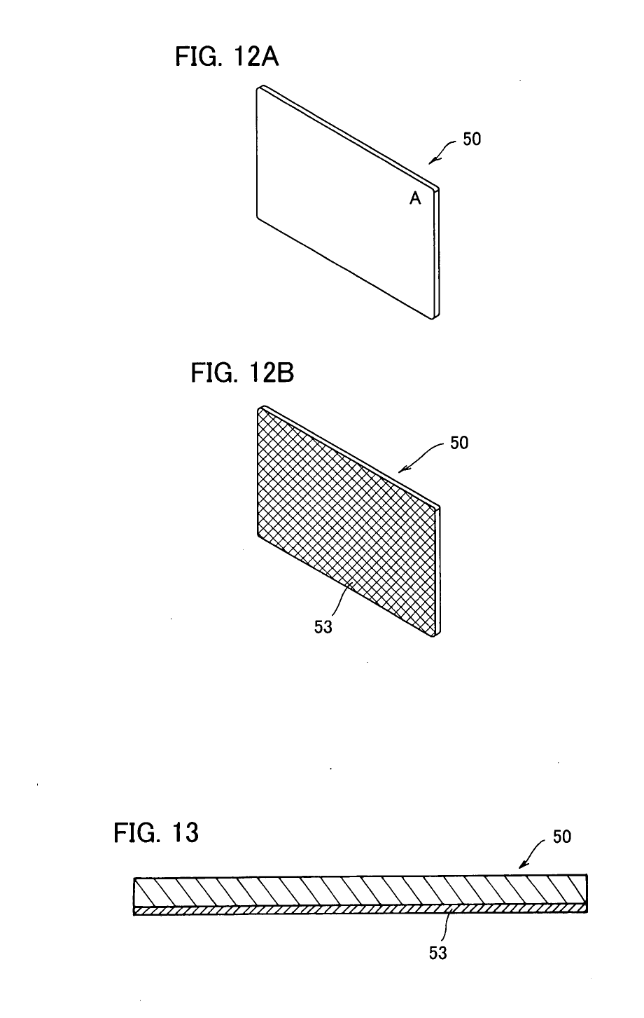

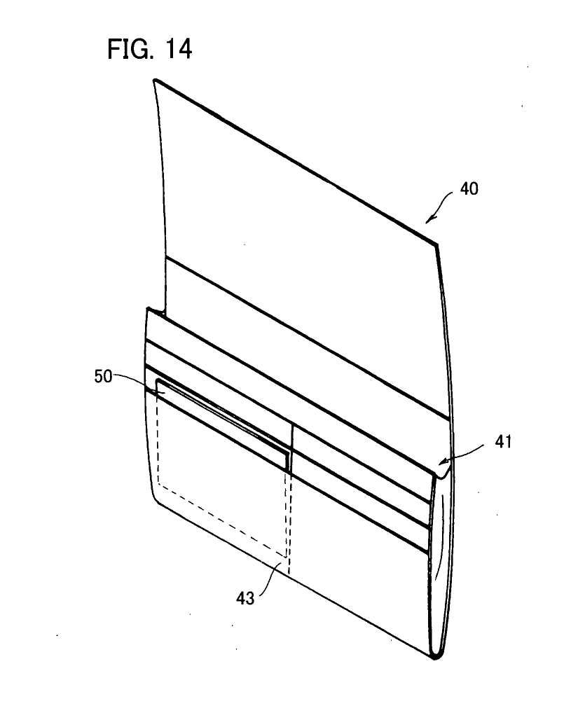

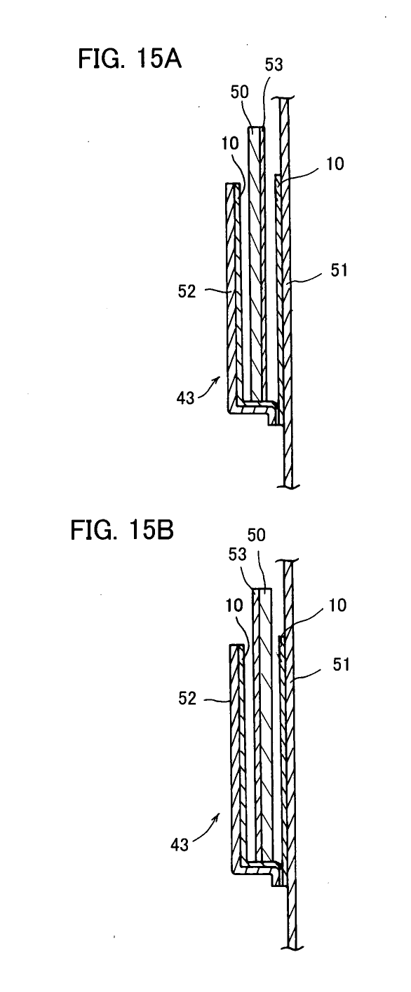

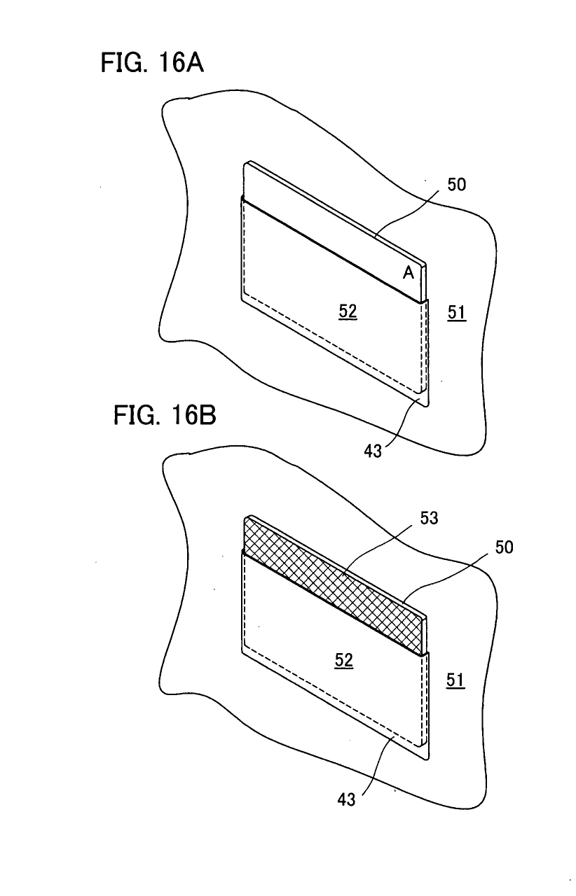

FIG. 10 is a perspective view of a wallet of fourth embodiment of the present invention. FIG. 11 is a perspective view of the wallet in FIG. 10 in an opened condition. FIGS. 12A and 12B are view of a card of a fifth embodiment of the present invention desirable to be inserted into the wallet in FIG. 10, FIG. 12A being a view of a front face of the card, and FIG. 12B being a view of a back face of the card. FIG. 13 is a cross sectional view of the card in FIG. 12. FIG. 14 is a perspective view of the wallet in FIG. 10 in which the card is inserted. FIGS. 15A and 15B each are a cross sectional view of a pocket of the wallet in FIG. 10 in which the card is inserted. FIGS. 16A and 16B each are a perspective view of the pocket of the wallet in FIG. 10 in which the card is inserted.

A wallet 40 of the present embodiment has a twofold structure with a bank bill insertion part 41, which has a plurality of card insertion pockets 43 at its entire surface. The card insertion pocket 43 has a depth shallower than a height of a card 50, so that the card 50 is inserted into the pocket 43 such that part of the card 50 is exposed outside of the pocket 43, as shown in FIG. 14.

Referring to FIG. 15, the card insertion pocket 43 is formed by an inner wall 51 facing a main body of the wallet 40 and an outer wall 52 defining a swell of a pocket. In the present embodiment, the laminated film (protection film for preventing leakage of information) 10 is attached to the entire inner surface of the pocket 43. Specifically, the laminated film 10 is sewed onto the inner surfaces of the inner and outer walls 51 and 52.

Further, the card 50 employed in the present embodiment has an aluminum foil (electromagnetic wave shielding layer) 53 attached to the entire surface of one side. Thus, the card 50 radiates electromagnetic wave only from the other side and not from the side to which the aluminum foil 53 is attached. Referring to FIGS. 12A, 12B, 16A, and 16B, the aluminum foil 53 is attached to a surface of a hatched side, the surface being a nonradiant surface of electromagnetic wave. A side showing a letter “A” is a radiant surface of electromagnetic wave.

By the wallet 40 of the present embodiment, in order to make a card reader to read out information without taking the card 50 out of the pocket 43, as shown in FIGS. 15A and 16A, the card 50 is to be inserted in the pocket 43 so that the radiant surface of electromagnetic wave of the card 50 faces the outer wall 52.

In the present embodiment, as described above, the card 50 is inserted in the pocket 43 with part thereof exposed outside, so that electromagnetic wave is radiated from the exposed part, thereby allowing a noncontact card reader to read out information recorded in the card 50.

Conversely, when the card 50 is inserted into the pocket 43 so that the side to which the aluminum foil 53 is attached faces the outer wall 52, electromagnetic wave is prevented from leaking outside. That avoids skimming.

Further, since the present embodiment has a plurality of card insertion pockets 43, if a card contains information to be read out without taking the card out of the pocket, the card should be inserted into the pocket 43 with the radiant surface of electromagnetic wave facing the outer wall 52, and if not, the card should be inserted into the pocket 43 with the nonradiant surface facing the outer wall 52. That would be convenient.

Next, other embodiments of the present invention will be described in detail below.

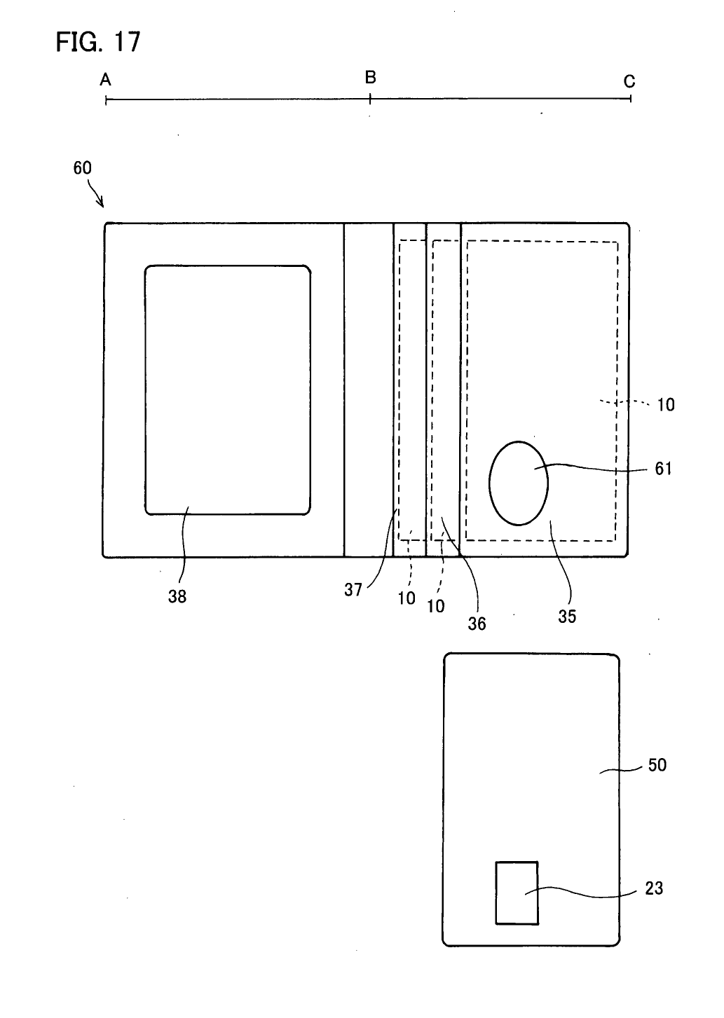

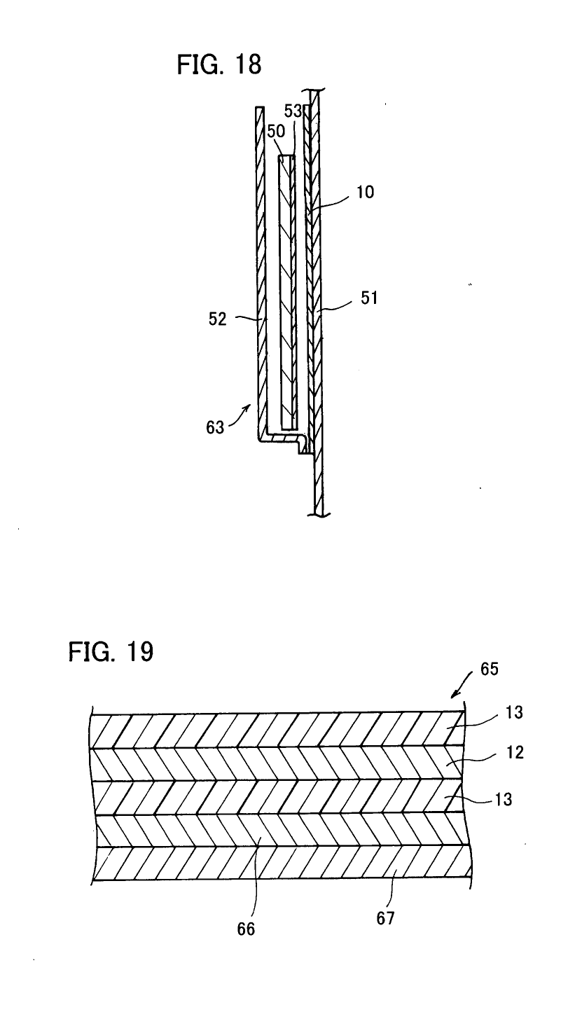

FIG. 17 is a front view of a modified embodiment of the pass holder in an opened condition and a front view of a card. FIG. 18 is a cross sectional view of a pocket of another modified embodiment of the pass holder in which the card is inserted.

These embodiments are modified embodiments of those in FIGS. 10 to 16B. In the above-mentioned embodiments, the card insertion pocket 43 has a smaller depth so as to produce the exposed part of a card, through which electromagnetic wave is radiated.

In contrast, a pass holder 60 shown in FIG. 17 has a card insertion pocket 35 that has a depth enough for a card 50 fit inside and that is provided with a hole 61. The hole 61 is located at a portion corresponding to a position of an IC chip 23 of the card 50.

By the pass holder 60 of the present embodiment, electromagnetic is wave is radiated through the hole 61. Other structures are the same as those in the above-mentioned pass holder 30 shown in FIG. 9.

Further, as shown in FIG. 18, a laminated film (protection film for preventing leakage of information) 10 may be attached to only an inner wall 51 and not to the outer wall 52. In the present embodiment, the outer wall 52 is permeable of electromagnetic wave, so that insertion of a card 50 with a radiant surface of electromagnetic wave facing the outer wall 52 allows a noncontact card reader to read out information recorded in the card 50 without taking the card 50 out of a pocket 63.

Next, modified embodiments of the laminated film 10 will be described in detail below. FIGS. 22 to 27 each are an enlarged cross sectional view of a modified embodiment of the laminated film (protection film for preventing leakage of information) 10.

As described above, the laminated film 10 may have more than two layers, and more specifically, it is recommended to have such a layer structure as shown in FIGS. 22 to 27.

A laminated film 10 shown in FIG. 22 has a resin layer 13 such as polyethylene terephthalate or polyethylene, two aluminum deposited layers 12 laminated on and sandwiching the resin layer 13, two resin layers 13 laminated on the aluminum deposited layers 12, and two carbon layers 80 laminated on the resin layers 13 as the outermost layers. The resin layers 13 each are 20 to 30 micrometers in thickness. The aluminum deposited layers 12 each are about 100 to 500 angstroms.

Herein, aluminum foil may be used instead of the aluminum deposited layers 12, so that the aluminum foil and a resin layer 13 glue together by an agent such as an adhesive agent.

The carbon layers 80 at the opposite sides each contain carbon compound having conjugated double bond.

A carbon compound having conjugated double bond has a function of absorbing electromagnetic wave, so as to absorb electromagnetic wave leaking from a card.

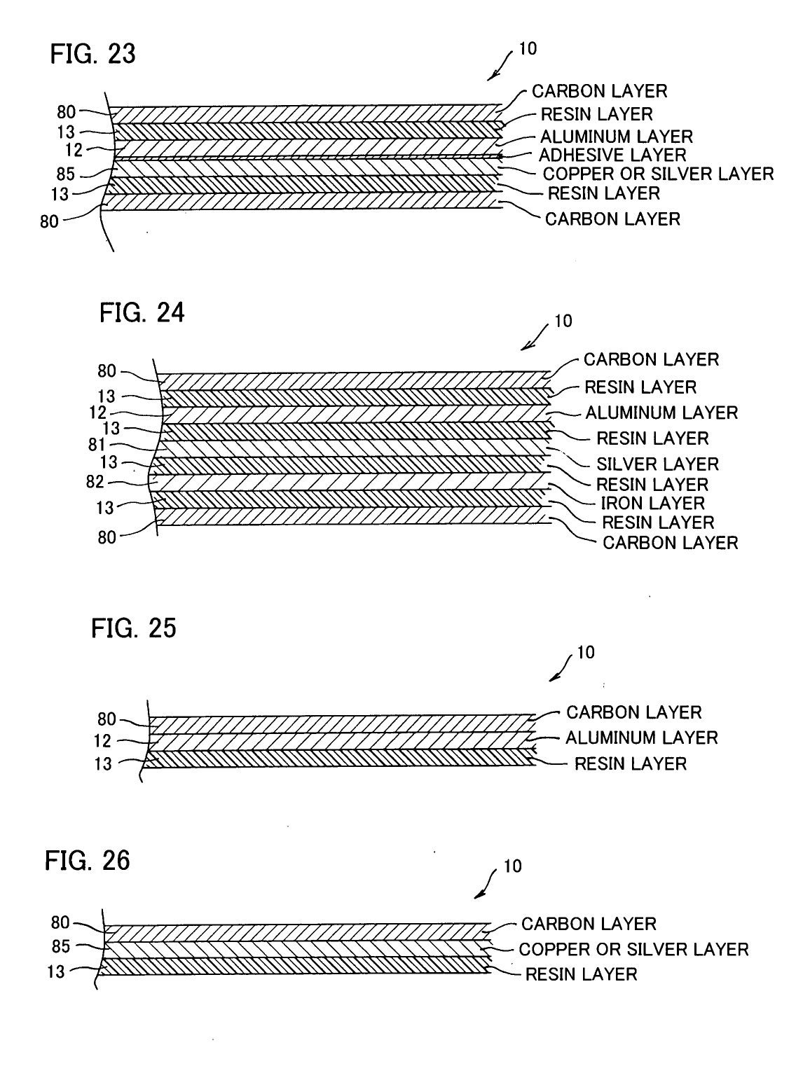

A laminated film 10 shown in FIG. 23 contains layers of different metals, that is, a copper or silver layer 85 is laminated on an aluminum foil layer 12. The copper or silver layer 85 may be bonded by vapor deposition or may glue together by an agent such as an adhesive agent after rendering it metallic foil. In the present embodiment, the aluminum foil layer 12 and the copper or silver layer 85 glue together by an adhesive agent.

The present embodiment contains layers of different metals and has a high function of shielding electromagnetic wave even if a card has any kind of frequency. Specifically, a capacity of shielding electromagnetic wave is influenced by a frequency of electromagnetic wave to be shielded, but relationship between the frequency and the shielding capacity depends on a metal. Aluminum, for example, has a shielding capacity increasing with its frequency, but has an extremely decreased shielding capacity if the frequency excesses a predetermined value. In contrast, silver has no appreciable decreased shielding capacity. Further, aluminum is inexpensive and silver is effective.

The present embodiment contains an aluminum layer and a silver layer, thereby reducing influence by a frequency and exerting a stable shielding function in any frequency range.

A laminated film 10 shown in FIG. 24 further contains an iron layer 82. Specifically, the laminated film 10 shown in FIG. 24 contains metal layers 12, 81, and 82; that is, an aluminum foil layer 12, a silver layer 81, and the iron layer 82. Resin layers 13 such as polyethylene terephthalate are sandwiched between the metal layers 12 and 81 and between the metal layers 81 and 82. Further, at the outermost layers, carbon layers 80 are laminated on other resin layers 13 such as polyethylene terephthalate laminated on the metal layers 12 and 82.

The laminated film 10 of the present embodiment has the iron layer 82, thereby shielding also magnetism. Further, a lead layer may be added thereto, or a lead layer may be provided instead of the iron layer 82 or the silver layer 81.

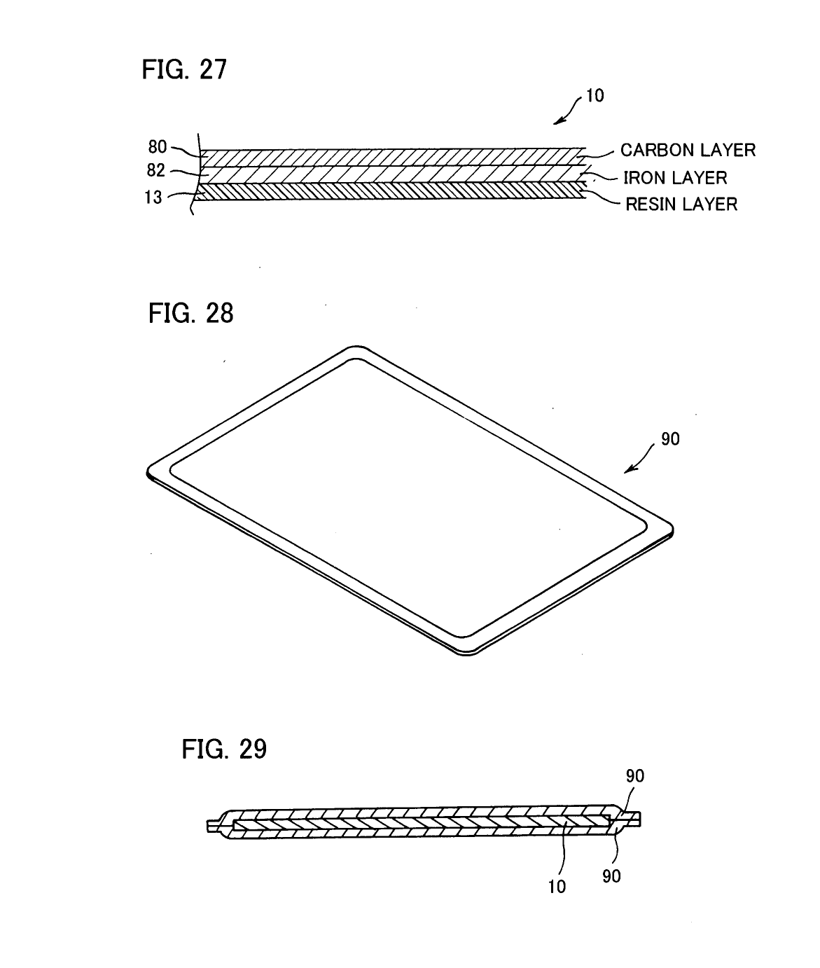

The above-mentioned embodiments each have an elaborate laminated structure, but as shown in FIG. 25, it is also possible to employ such a structure as containing an aluminum foil layer 12 with a carbon layer 80 laminated on one side thereof and a resin layer 13 laminated on the other side thereof. Further, as shown in FIG. 26, it is possible to employ such a structure as containing a silver or copper layer 85 instead of an aluminum foil layer 12 with a carbon layer 80 laminated on one side thereof and a resin layer 13 laminated on the other side thereof. Still further, as shown in FIG. 27, it is possible to employ such a structure as containing an iron layer 82 instead of an aluminum foil layer 12 with a carbon layer 80 laminated on one side thereof and a resin layer 13 laminated on the other side thereof. A lead layer may be provided instead of the silver or copper layer 85 or the iron layer 82.

Next, other applications of the protection film for preventing leakage of information of the present invention will be described in detail below.

The protection film prevents leakage of electromagnetic wave not only from a pouch but also from a container or a storage for articles. Specifically, the protection film attached to an outer or an inner surface of such container by adhering or sewing prevents leakage of electromagnetic wave. The protection film may be attached to curtains or wall papers. Further, the protection film may be directly stuck on walls.

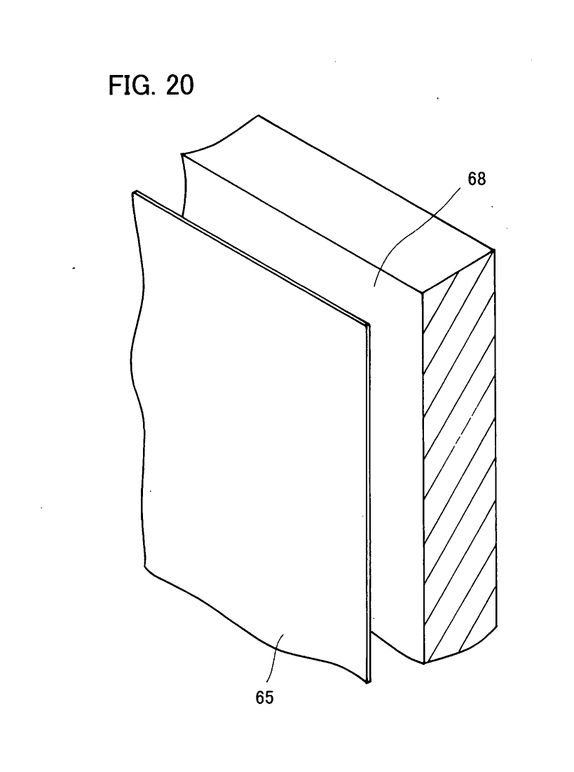

FIG. 19 is an enlarged cross sectional view of a protection film for preventing leakage of information to be stuck on a wall. FIG. 20 is a perspective view of the protection film in FIG. 19 in being stuck on a wall.

Referring to FIG. 19, a protection film 65 for preventing leakage of information to be stuck on a wall contains an aluminum foil layer 12 with resin layers 13 laminated on both side thereof and an adhesion layer 66 and a removable paper layer 67 laminated on one of the resin layers 13. The protection film 65 is stuck on a surface of a wall 68, as shown in FIG. 20, by removing the removable paper layer 67 on the back.

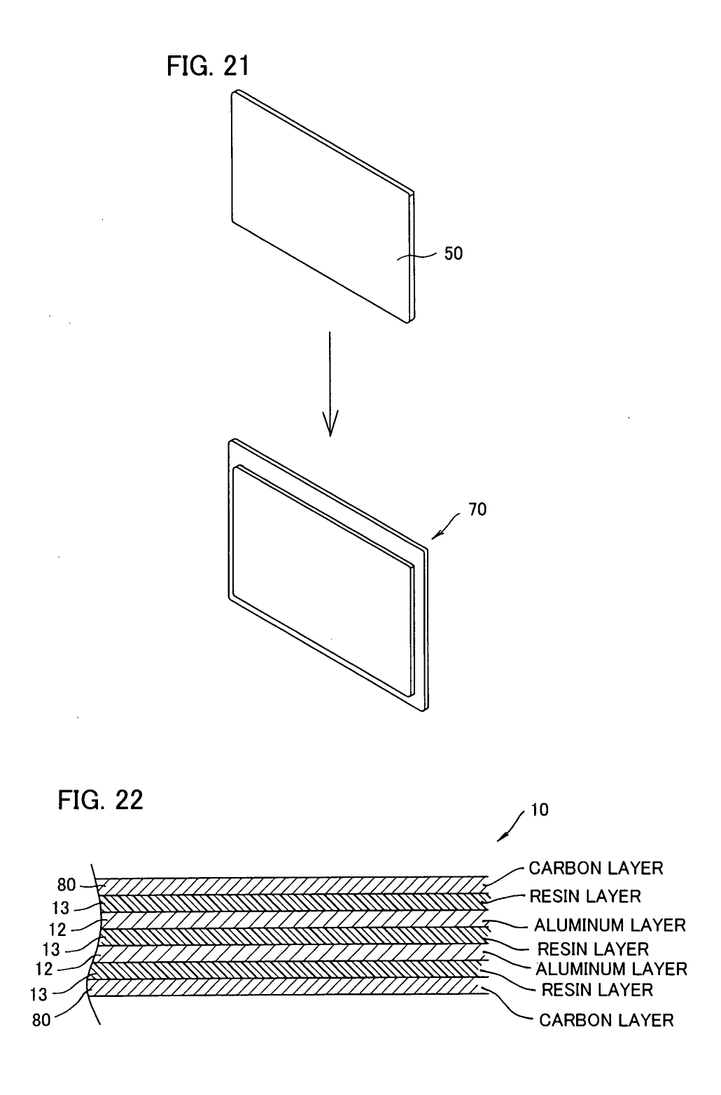

Further, the protection film may be directly used for producing a container. FIG. 21 is a perspective view of a card case made by a protection film for preventing leakage of information of a sixth embodiment of the present invention.

In order to produce a card case 70 of the present embodiment, two protection films for preventing leakage of information are stacked and heat-sealed at three sides. The card case 70 has a bag-like shape and can accommodate a card 22.

Further, an information-leakage preventing plate 90 as shown in FIG. 28, which is produced by putting a laminated film 10 between laminated sheets, is also convenient. Specifically, the preventing plate 90 is produced, as shown in FIG. 29, in such a manner that the laminated film 10 is interposed between two heat-sealing sheets and heat-sealed all together. Herein, the preventing plate 90 may have one laminated film 10 or more than one laminated film 10. Specifically, a large number of the laminated films 10 having the same thickness are produced and a plurality of the films 10 are used and stacked to attain a thickness according to need. In particular, some thickness of the preventing plate 90 has little bad effect, so that a plurality of laminated films 10 can be interposed between laminated sheets with the emphasis on safety.

The preventing plate 90 has the same size as the card 50 described above, being a business card size.

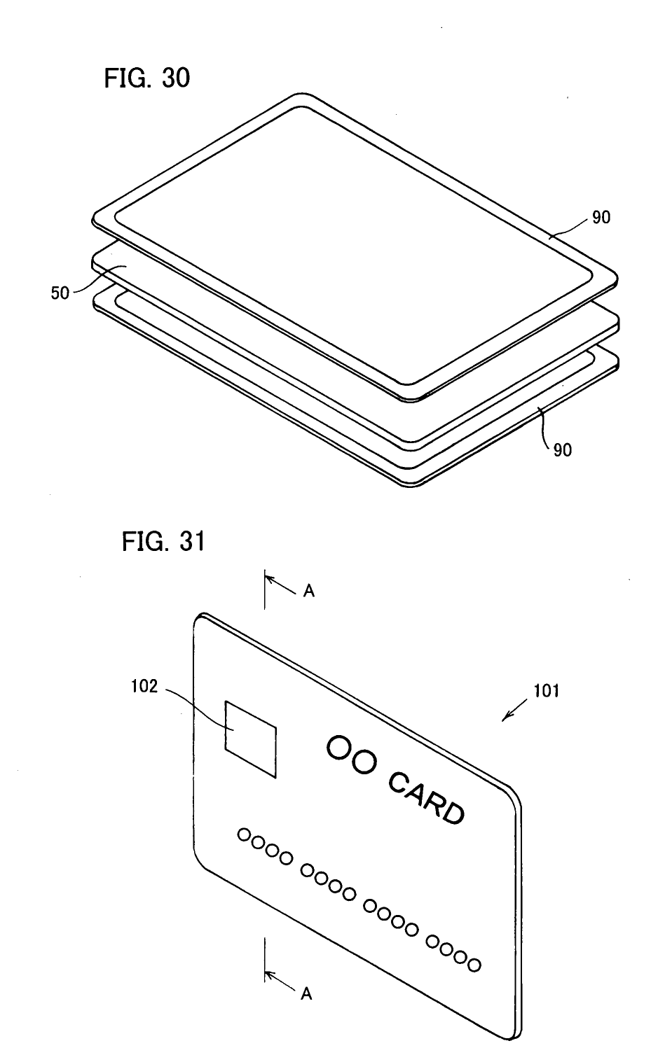

The preventing plate 90 is used, for example, in such a manner that two plates 90 are put in a wallet or a card case so as to be in contact with both sides of the card 50, as shown in FIG. 30. In the present embodiment, the laminated film 10 incorporated in the preventing plate 90 shields electromagnetic wave, thereby preventing electromagnetic wave emitted from the card 50 from leaking outside. That avoids skimming.

In the embodiment shown in FIG. 30, two preventing plates 90 interpose the card 50 therebetween, but only one preventing plate 90 contacting with one side of the card 50 is expected to provide appreciable preventive effect against skimming. In particular, the use of a laminated film 10 containing a layer effective in absorbing electromagnetic wave, such as a carbon layer, weakens electromagnetic wave leaking outside, helping skimming prevention.

Next, embodiments of the present invention relating to a card will be described in detail below.

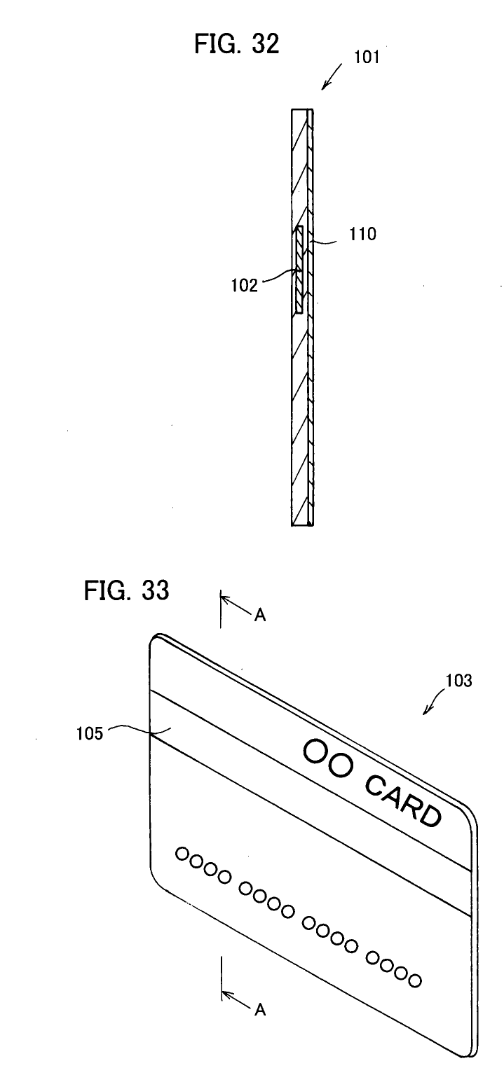

FIG. 31 is a perspective view of a modified embodiment of the card of the present invention. FIG. 32 is a cross sectional view of the card in FIG. 31 taken along a line A-A.

A card 101 of the present embodiment is a credit card, incorporating an IC chip (information storing medium) 102. The card 101 has information stored in the IC chip 102, whose memory content is read out by holding the card 101 over a card reader not shown.

The card 101 is mainly made of hard resin as heretofore known, but the present embodiment especially has a laminated barrier 110 at its back. The barrier 110 has a function of shielding or attenuating electromagnetic wave and magnetism.

The barrier 110 is attached to only one side of the card 101 embedding the IC chip 102 therein.

The barrier 110 is of a plate-like shape or a film shape and can use a laminated sheet made of metal and resin of the same material and structure as the above-mentioned laminated film (protection film for preventing leakage of information) 10 or a metal film such as aluminum.

The above-mentioned card of the present invention has the barrier, presenting a lower sensitivity compared to normal cards. That allows lower risk to skimming during commuting.

Specifically, important cards such as a bank card and a credit card are carried, not naked, with inserted in a card case, and further in a pocket or a bag.

Thus, even if a skimmer intends to bring a card reader close to the cards during commuting, the card reader cannot be brought into contact directly with the cards.

Herein, the card of the present invention has the barrier so as to intentionally decrease sensitivity of the card. That allows lower risk to skimming during commuting.

Further, since the card of the present invention has a lower sensitivity than that of normal cards, the card must be brought within striking distance of a card reader when being used. However, the above-mentioned important cards such as a bank card and a credit card are usually used on nearly contact with a card reader, rendering no inconvenience for users.

The card 101 of the present embodiment is expected to be carried with inserted in a card case or a wallet.

The card 101 has at its one side the laminated barrier 110, whereby electromagnetic wave emitted from the IC chip 102 of the card 101 is attenuated, thereby being resistant to skimming. Further, the barrier 110 laminated on the card 101 decreases influence of external magnetism generated by a foreign reader, thereby preventing the IC chip 102 from reacting to the external magnetism. That is resistant to skimming.

According to the experiment by the present inventor, the card 101 of the present embodiment reacts when being brought within 2 mm from a card reader and avoids reading of memory content from the IC chip when being away more than 2 mm.

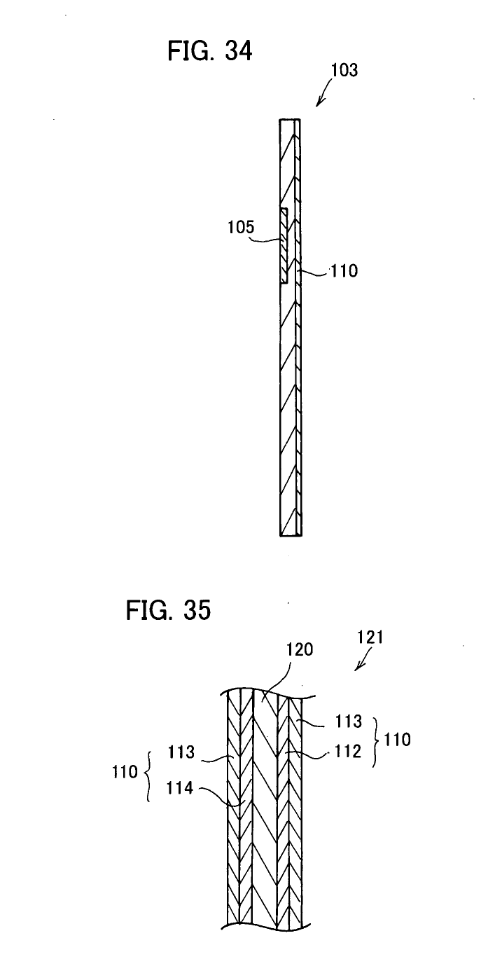

FIG. 33 is a perspective view of another modified embodiment of the card of the present invention. FIG. 34 is a cross sectional view of the card in FIG. 33 taken along a line A-A. FIGS. 35 to 37 are enlarged cross sectional views of other modified embodiments of the card of the present invention.

The above-mentioned card 101 uses the IC chip 102 as an information storing medium, but the present invention is not limited to an IC chip as the medium. As in a card 103 shown in FIGS. 33 and 34, for example, a magnetic storing medium 105 may be provided. Referring to FIG. 34, the card 103 has a barrier 110 laminated on its one side (front face).

Further, in the above-mentioned embodiment, the barrier 110 is laminated on one side of the card 103, but as shown in the cross sectional view of a card 121 shown in FIG. 35, a barrier 110 may be attached to both sides of a layer 120 embedding an IC chip therein. The barrier 110 is formed by lamination of an aluminum layer 112 and a resin layer 113, the resin layer 113 being arranged at the outermost.

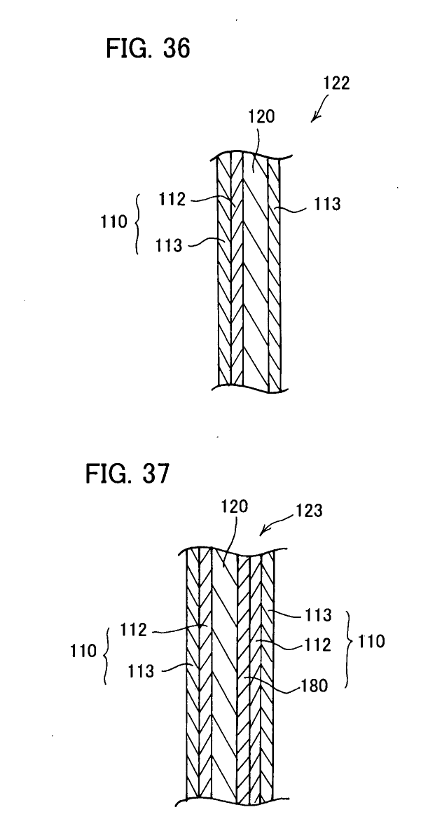

A card 122 shown in FIG. 36 contains a layer 120 embedding an IC chip therein with a barrier 110 attached to one side of the layer 120 and a resin layer 113 attached to the other side thereof. The barrier 110 of the card 122 is also formed by lamination of an aluminum layer 112 and a resin layer 113.

Further, a card 123 shown in FIG. 37 contains a layer 120 embedding an IC chip therein with a barrier 110 composed of an aluminum layer 112 and a resin layer 113 attached to one side of the layer 120 and another barrier 110 composed of a carbon layer 180, an aluminum layer 112, and a resin layer 113 attached to the other side thereof.

In the foregoing embodiment, the barrier 110 is laminated on a front face or a back face of the card 101, but may be laminated within the card 101. The barrier 110 may be laminated on only a portion where the storing medium such as the IC chip 102 is disposed.

The barrier 110 may be preliminary laminated on the cards 101 and 103, but may be laminated on an existing card afterward by adhering. Specifically, the barrier 110 is separately manufactured to be sold as a supplementary element for a card. A person who buys the barrier 110 provides against skimming by adhering the barrier 110 to his/her cards so as to intentionally decrease sensitivity of the medium such as the IC chip 102.

Next, a card used for advertising will be described in detail below.

In opening of a shop or for finding potential customers, an advertisement is performed so as to familiarize service contents to users. Brochures or giveaways are distributed on the street, for example. A bit of articles for sale may be given out so as to promote another visit to visitors. A matchbox (see JP 7-300384 A, for example) or tissue paper is representative of a distributed article. Recently, a prepaid card such as a telephone card is used as an article for advertisement.

However, distribution of an article such as a matchbox, tissue paper, and a telephone card has some questions on advertising effectiveness.

The article such as a matchbox includes a name or a telephone number of a shop printed thereon, but a person who receives the article may not carry it on a daily basis.

Matches are a kind of consumables, being used several times in smoking, and being disposed of with a box when matches therein are finished up. Therefore, a person who receives the matchbox will hold it for a week at most. As for tissue paper, it will be wasted away fast, being finished up in one use. That means a person who receives the tissue paper will hold it only before getting home.

As for a telephone card, it will be held for a slightly longer time, but only for a month around.

In many cases, the person does not have the article such as a matchbox when it comes to a time to need to use the shop.

Thus, the following embodiments will be disclosed so as to propose a new advertising medium and to prevent skimming using the medium.

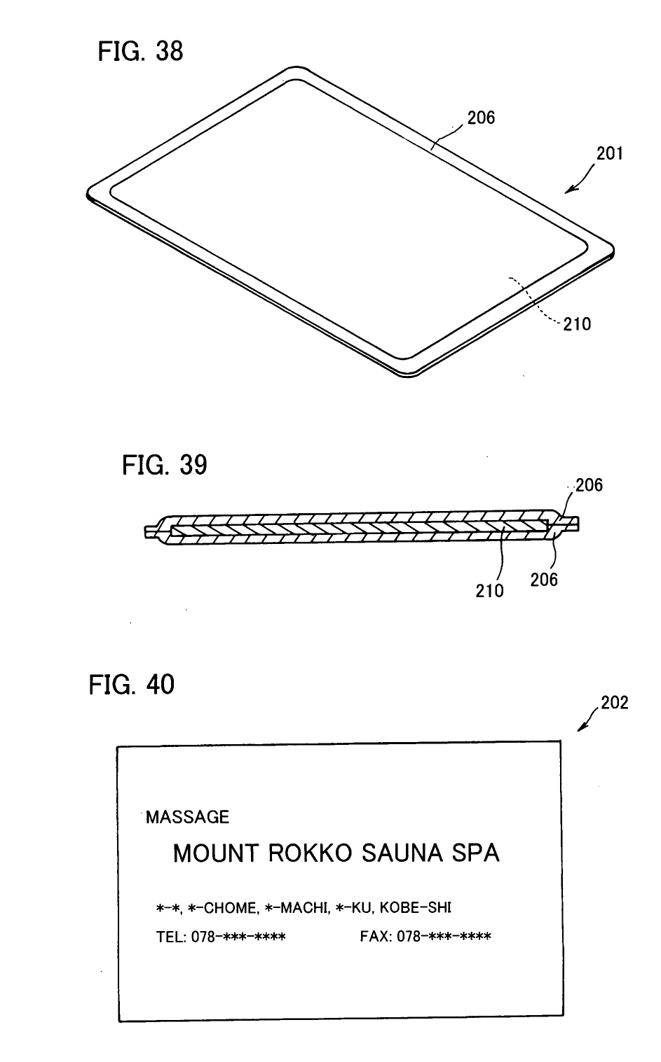

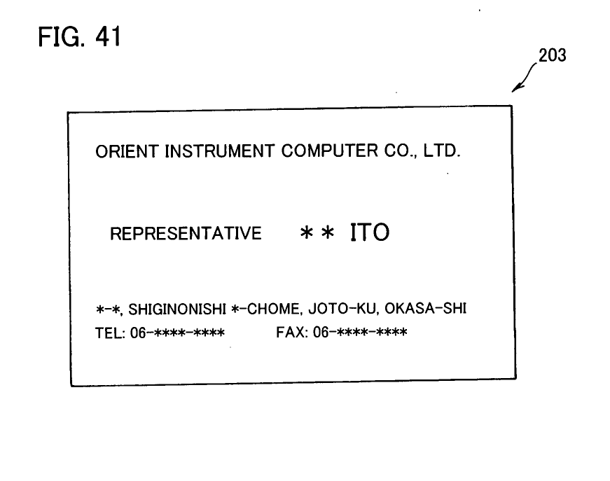

FIG. 38 is a perspective view of a skimming preventing card of an eighth embodiment. FIG. 39 is a cross sectional view of the skimming preventing card in FIG. 38. FIG. 40 is a front view of another skimming preventing card on which an advertisement is printed. FIG. 41 is a front view of still another skimming preventing card used as a business card.

A skimming preventing card 201 of the present embodiment has, as shown in FIG. 39, two-layered surface sheets 206, between which electromagnetic wave/magnetism shielding member 210 is sandwiched, the three being adhered.

The surface sheets 206 each are a white polyvinyl chloride sheet, an ABS resin, or the like, and made of a material printable on its surface by the conventional means.

The shielding member 210 is of a plate-like shape or a film shape and can use a metal film such as an aluminum film or a laminated sheet made of metal and resin.

The shielding member 210 may be made of the same material and structure as the above-mentioned laminated film (protection film for preventing leakage of information) 10. Specifically, as shown in FIG. 3, the shielding member 210 is a laminated film composed of an aluminum foil layer (aluminum deposited layer) 12 and a resin layer 13.

Herein, the aluminum foil layer 12 preferably has a thickness of 8 micrometers or more and more preferably 18 micrometers or more.

The above-mentioned shielding member 210 has a two-layer structure, but may have a structure with three layers or more.

Further, a plurality of the shielding members 210 may be sandwiched between the surface sheets 206.

The skimming preventing card 201 of the present embodiment is used for advertisements, an advertisement being printed on a surface of the card 201. As shown in a skimming preventing card 202 shown in FIG. 40, information such as a shop name, service contents, an address, and a telephone number is printed thereon. As shown in FIG. 41, a skimming preventing card 203 may be used as a business card.

The preventing card 201 can be distributed free of charge on the street, for example. In the case of the preventing card 203 of a business card type as shown in FIG. 41, sales people can present the card 203 to a customer, explaining a function of the skimming preventing card 201, 202, and 203.

A person who receives the preventing card 201 will carry it in a card case or a wallet.

The preventing card 201 incorporates the electromagnetic wave/magnetism shielding member 210, which attenuates electromagnetic wave emitted from a card such as a credit card, thereby being resistant to skimming. The preventing card 201 incorporates the shielding member 210, which reduces influence of external magnetism emitted from a foreign reader, thereby preventing a card such as a credit card from reacting on the external magnetism. That is resistant to skimming.

Next, other applications of the skimming preventing card of the present invention will be described in detail below.

The skimming preventing card of the present invention is intended to be developed as an advertising medium, but the present invention does not restrict other applications of the preventing card. The preventing card may be used for hobbies, for example.

More specifically, the preventing card may be used for printing photos of people such as loved one or children thereon so as to carry the card in a wallet or the like.

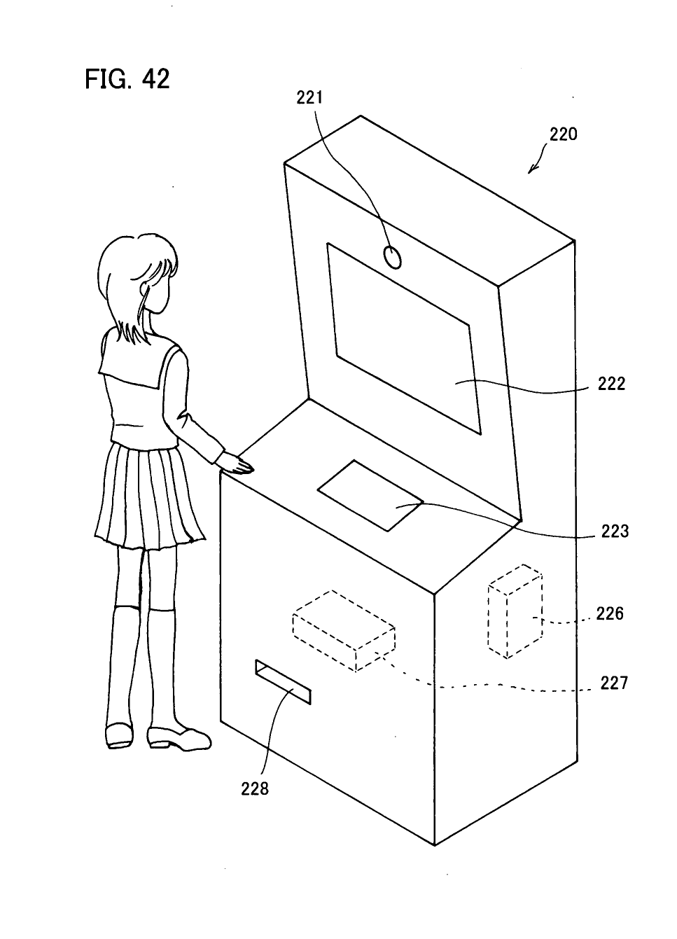

FIG. 42 is a perspective view of a card printer used for printing a photo on a skimming preventing card.

A card printer 220 can be placed at a game arcade, for example. Recently, some game arcades issue a Reward Card, to which points are added each time of playing a game. Various services are presented based on the number of points.

Some game consoles such as video games issue a card in which information such as a user's history is recorded. Information such as a score of a past game, a type of an opponent character in a game, points obtained by defeating the character, and weapons allowed for use in a game can be recorded in the card.

Game players are worried about stealage of their own points by skimming. Thus, installation of a card printer at a place such as a game arcade meets the requirement.

The card printer 220 includes a camera 221 for shooting photos, a monitor 222, and an operating panel 223.

There is provided with a casing 225, which houses a card containing section 226 for accommodating therein unprinted skimming preventing cards, and a printer (a printing section) 227.

Further, the casing 225 is provided with a slot 228 through which a printed skimming preventing card is to be taken out.

A user stands in front of the camera 221 and draw a rough sketch while watching the monitor 222. The operating panel 223 is operated so as to input letters, characters, or other decorations to be printed.

The printer 227 prints a photo on an unprinted skimming preventing card. The printed skimming preventing card 205 is ejected from the slot 228.

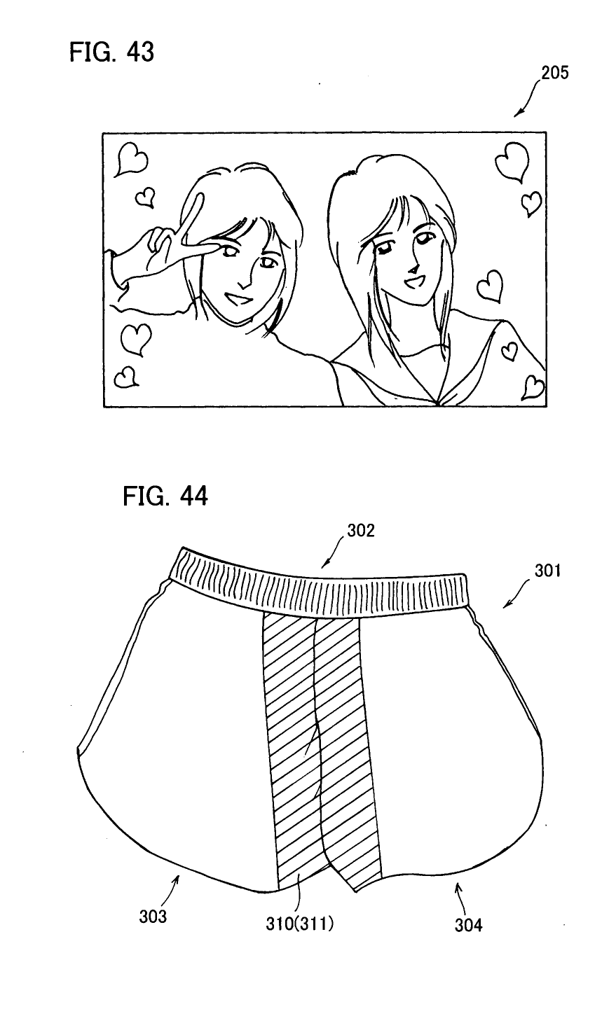

The ejected card 205 is, for example, as shown in FIG. 43, a card on which a photo of the users is printed.

As described above, the portable pouch or the card case of these embodiments shields electromagnetic wave emitted from a card, preventing skimming.

Hereafter, other embodiments of the present invention will be described.

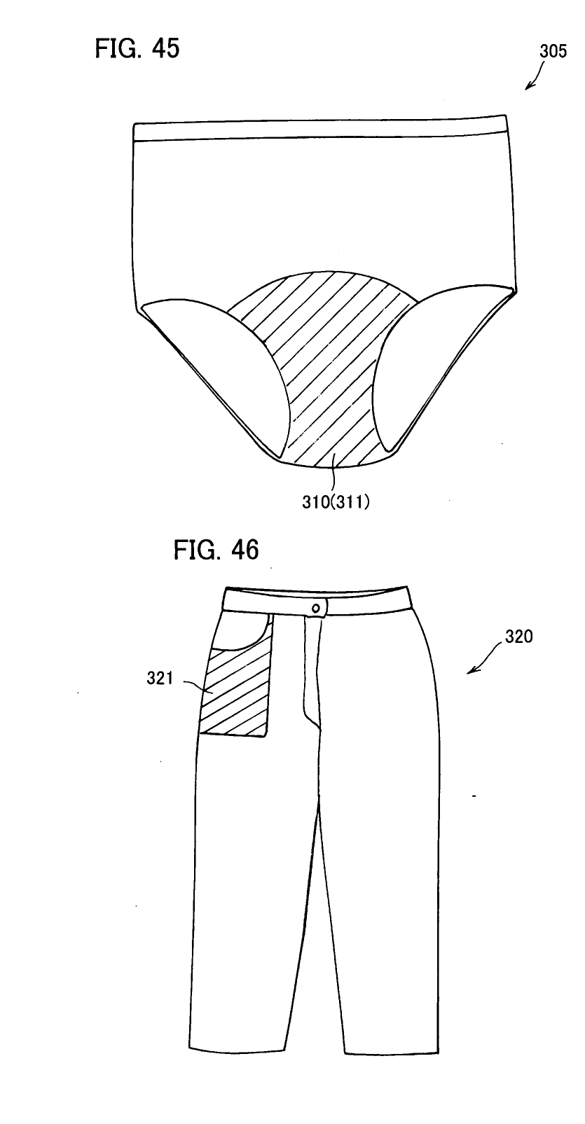

FIG. 44 is a front view of underwear (men's) of a ninth embodiment of the present invention. FIG. 45 is a front view of panties (ladies') of a tenth embodiment of the present invention.

Underwear 301 shown in FIG. 44 are of a trunks style, including a trunk insertion part 302 and leg insertion parts 303 and 304 as well as the known art, and for covering testes and a penis. In the present embodiment, a laminated film 310 is laminated on a cloth of an area (hatched area, for example) corresponding to wearer's testes and penis.

Panties 305 shown in FIG. 45 have a laminated film 310 laminated on a cloth of an area (hatched area, for example) corresponding to wearer's uterus and ovaries.

In the present embodiments, the laminated film 310 is attached to an outer surface of a cloth of the underwear 301 or the panties 305 by sewing.

The laminated film 310 may be made of the same material and structure as the above-mentioned laminated film (protection film for preventing leakage of information) 10. Specifically, as shown in FIG. 3, the laminated film 310 is a laminated film composed of an aluminum foil layer 12 and a resin layer 13.

Herein, the aluminum foil layer 12 preferably has a thickness of 8 micrometers or more and more preferably 18 micrometers or more.

The above-mentioned laminated film 310 has a two-layer structure, but may have a structure with three layers or more.

As well as the above-mentioned laminated film (protection film for preventing leakage of information) 10, the resin layer 13 may be made of any material only if it is a known resin capable of being made into a film.

Instead of the laminated film 10, a cloth (electromagnetic wave shielding cloth) 311 in which metallic yarn is woven may be used. The metallic yarn is preferably made of aluminum or silver. The metallic yarn woven into the cloth 311 preferably makes up 10% or more of the total number of yarn constituting the cloth 311. Further, the metallic yarn woven into the cloth 311 preferably makes up 50% or less thereof. Most preferably, the metallic yarn makes up 25 to 35% thereof.

In the case of underclothing, for example, the cloth 311 is preferably a fabric such as a plain weave fabric, a twill fabric, and a flannel (cotton flannel), but can be a knit.

The embodiments above described includes only the example in which the laminated film 310 or the cloth (electromagnetic wave shielding cloth) 311 is attached to a portion corresponding to testes or ovaries, but the film 310 or the cloth 311 may be attached to the entire portion of the underwear. Further, the laminated film 310 or the cloth 311 may be used for sewing underclothing.

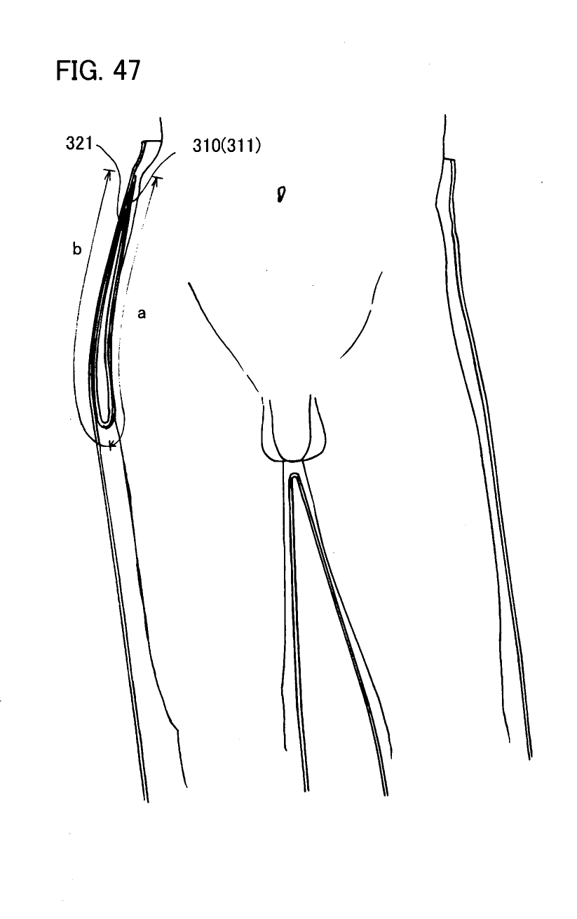

The laminated film 310 may be attached to underclothing such as long underwear, long pants, and a brassiere other than underwear or panties. Further, the laminated film 310 or the cloth 311 may be attached to garments other than such underclothing. FIG. 46 is a front view of trousers of an eleventh embodiment of the present invention. FIG. 47 is a schematic diagram showing inside of the trousers in FIG. 46.

Trousers 320 shown in FIG. 46 have a pocket 321, which is made by sewing a sac-like member onto an inner side of the trousers 320, as well as the conventional art. The laminated film 310 or the cloth 311 is attached to only an area A to face a human body of the sac-like member, whereas the laminated film 310 or the cloth 311 is not attached to an area B to face outside.

Since the trousers 320 of the present embodiment has the laminated film 310 or the cloth 311 attached to the area A to face a human body of the pocket 321, electromagnetic wave emitted from a mobile phone contained in the pocket 321 does not penetrate toward the human body. That protects his testes.

In contrast, since the laminated film 310 or the cloth 311 is not attached to the area B to face outside, a mobile phone receives electromagnetic wave from outside.

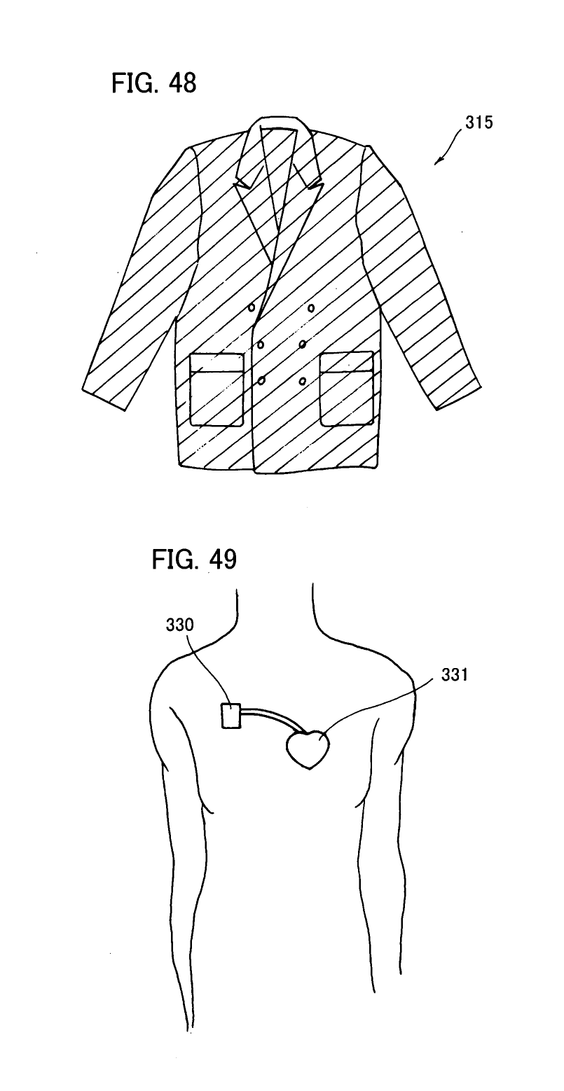

The clothing described above each are worn on a lower part of one's body, but the present invention is applied to a clothing worn on an upper part of one's body such as a jacket. FIG. 48 is a front view of a jacket of a twelfth embodiment of the present invention.

A jacket 315 of the present embodiment uses a laminated film 310 or a cloth (electromagnetic wave shielding cloth) 311 as a lining.

One applying the present invention to a clothing worn on an upper part of one's body, such as a jacket, is recommended to a user of an electronic health supportive device such as a pacemaker wearer.

Next, an embodiment of a clothing recommended to a pacemaker wearer will be described below.

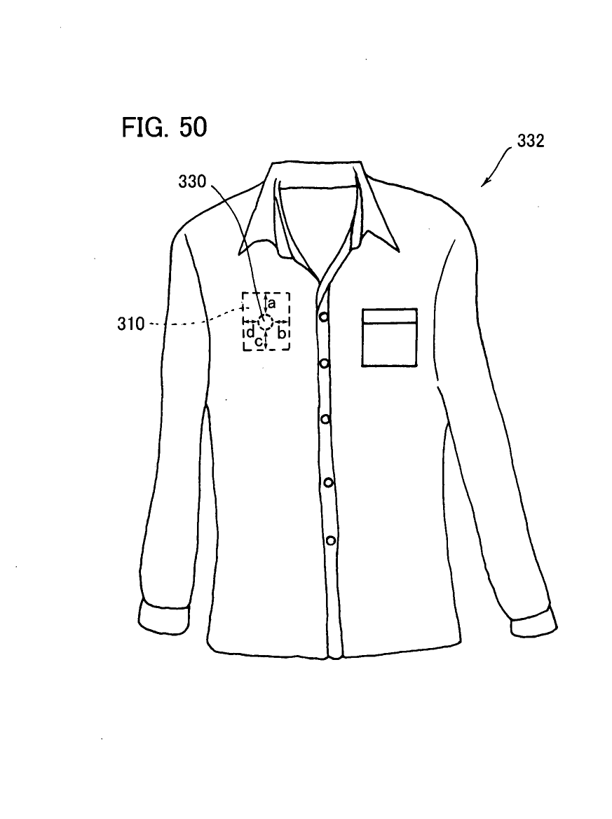

FIG. 49 is a perspective view showing a human body of a pacemaker wearer. FIG. 50 is a perspective view of a clothing worn by the pacemaker wearer in FIG. 49.

A pacemaker 330 transmits electric signals to a heart 331 as well known, and is embedded in a wearer's body. The pacemaker 330 is embedded in a position depending on a body type of a wearer, and mostly in a right chest as shown in FIG. 49 or in a left chest. Some pacemaker is embedded in an abdomen.

A clothing 332 shown in FIG. 50 is a shirt with a laminated film 310 sewn onto a portion corresponding to a chest. Specifically, the laminated film 310 is attached to a left chest portion of the clothing 332 where the pacemaker 330 is embedded.

The larger the laminated film 310 is, the better, but at least the laminated film 310 is necessary to have a size enough to cover the pacemaker 330.

Further, it is recommended that distances a, b, c and d from the pacemaker 330 to edges of the laminated film 310 each are 11 cm or more.

Specifically, 22 cm or more between the pacemaker 330 and a mobile phone (not shown) is supposed not to cause malfunction of the pacemaker 330 by electromagnetic wave of the mobile phone.

Herein, on the assumption that a mobile phone is situated in front of the laminated film 310 and in the center of the pacemaker 330, electromagnetic wave reaches the pacemaker 330 bypassing the laminated film 310. Thus, in this case, the electromagnetic wave bypasses the distances a, b, c and d to reach the pacemaker 330. If and when a bypass composed of the distances a, b, c, and d has a length of 22 cm or more, the mobile phone does not cause malfunction of the pacemaker 330. Consequently, as described above, the distances a, b, c, and d from the pacemaker 330 to the edges of the laminated film 310 each are preferably 11 cm or more.

In the present embodiment, the laminated film 310 is attached to only the front of one's body, but preferably also to the back of the body.

Next, an experiment performed by the present inventor will be described below.

In the experiment, a pacemaker was connected to a computer, to which a signal voltage generated by the pacemaker was inputted. A graph of the signal voltage and a graph of pulsed signals of the signal voltage were drawn. A mobile phone was placed adjacent to the pacemaker and made to receive a phone call.

As the embodiment of the present invention, the pacemaker was covered with the jacket 315 shown in FIG. 48, and the mobile phone adjacent to the pacemaker received a phone call. As a comparative example, the mobile phone received a phone call without the jacket 315. The jacket 315 used the laminated film 310 as a lining.

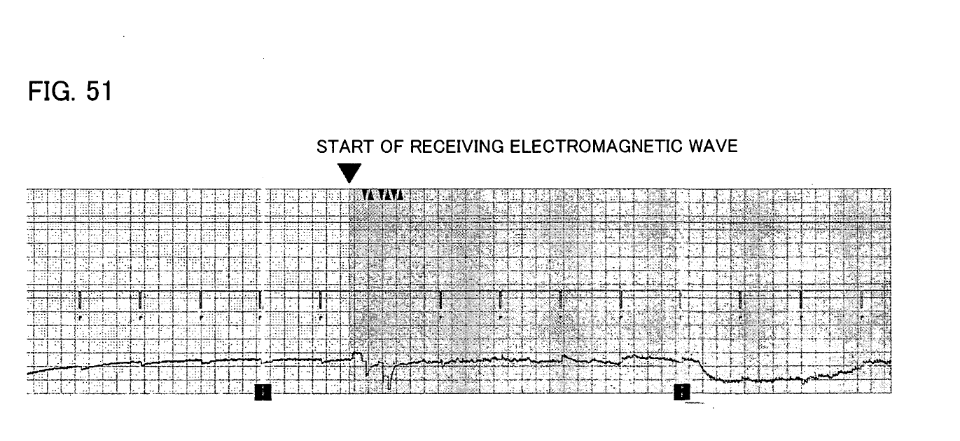

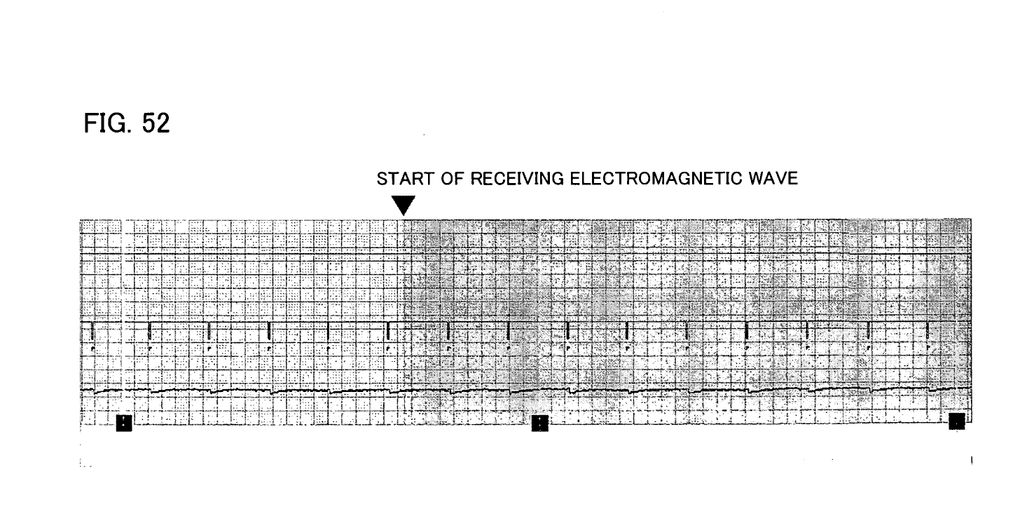

A graph of the comparative example is shown in FIG. 51. A graph of the embodiment is shown in FIG. 52. Specifically, FIG. 51 is the graph showing signals of the pacemaker supposed to be when the mobile phone is used in a vicinity of the pacemaker wearer/user. FIG. 52 is the graph showing signals of the pacemaker supposed to be when the mobile phone is used in a vicinity of the pacemaker wearer/user wearing the clothing of the present invention.

As shown in the graphs, when the mobile phone received a phone call without the jacket 315, a signal voltage generated from the pacemaker was corrupted, rendering pulse interval irregular. In contrast, when the mobile phone received a phone call with the jacket 315 over the pacemaker, signals generated from the pacemaker were the same before and after receiving the phone call and pulse interval was regularly.

Next, an embodiment relating to a mobile phone will be described below.

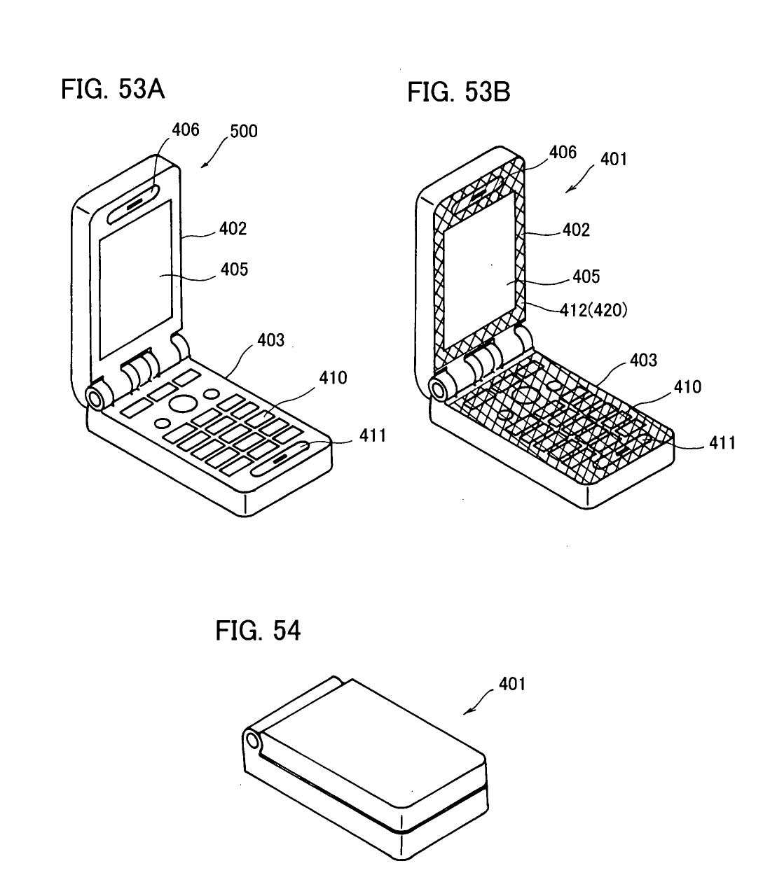

FIGS. 53A and 53B each are a perspective view of a mobile phone handset in use, FIG. 53A being a perspective view of a mobile phone handset of the conventional art, and FIG. 53B being a perspective view of a mobile phone handset of a thirteenth embodiment of the present invention. FIG. 54 is a perspective view of the handset of both the conventional art and the present invention when carried.

A mobile phone handset 500 shown in FIG. 53A is of the conventional art, whereas a mobile phone handset 401 shown in FIG. 53B is of the embodiment of the present invention.

The both handsets 500 and 410 have the same basic function and structure as a mobile phone handset and each have a twofold main body. Specifically, the handsets 401 and 500 each have two casings 402 and 403, which are connected by a hinge not shown.

In each of the handsets 401 and 500, the casings 402 and 403 are folded when carried as shown in FIG. 54, but are opened when used as shown in FIGS. 53A and 53B. As well as the publicly known one, the casings 402 and 403 each have an operating panel on an inner surface thereof.

Specifically, the casing 402 shown at the upper side of the figure has a display (viewing area) 405 in the center of the inner surface and a receiver 406 at the top of the inner surface. The receiver 406 incorporates a small speaker, which produces sounds.

The casing 403 shown at the lower side of the figure has a number of operating switches 410 and a microphone 411, as well as the publicly known one. A detailed description of the operating switches 410 and the microphone 411 is omitted because of common knowledge of one skilled in the art.

The mobile phone handset 401 of the present invention has a metal layer 412 laminated on a side to be in contact with one's ear when used. In the figure, the metal layer 412 is laminated on a hatched portion. In other words, the metal layer 412 is attached to an inner surface of each of the casings 402 and 403. However, a metal layer is not attached to a portion where the metal layer is technically difficult to be laminated, such as the display 405 and the operating switches 410.

The metal layer 412 is a thin film layer made of a material such as iron, nickel, and aluminum, having a thickness of 8 micrometers or more. Preferably, the thickness is 18 micrometers or more. Further, the metal layer 412 preferably has a structure with two layers or more. It is recommended that two or three metal layers, each layer of 8 micrometers or more, are laminated with sandwiching a resin layer in their middle part.

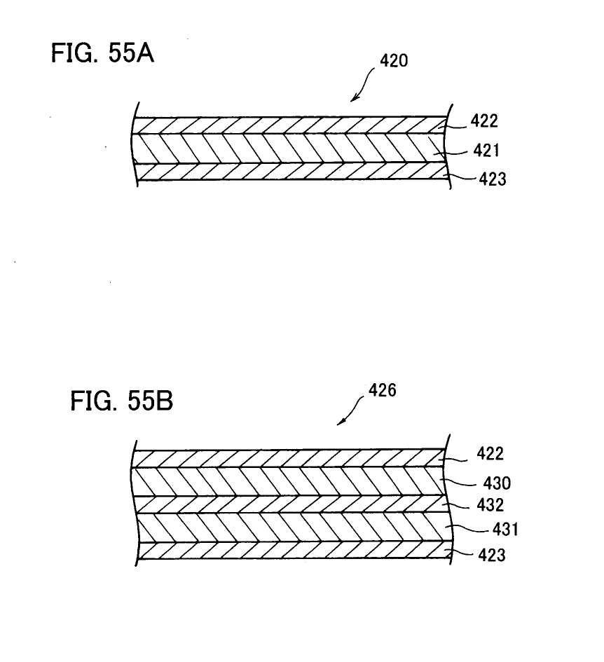

The metal layer 412 is attached to a surface of a body of the casing 402 by application of a sheet 420 shown in FIGS. 55A and 55B with an adhesive agent.

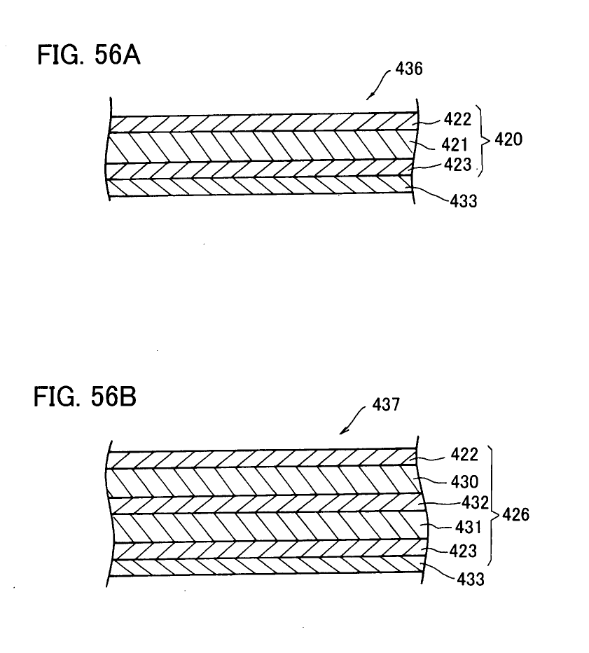

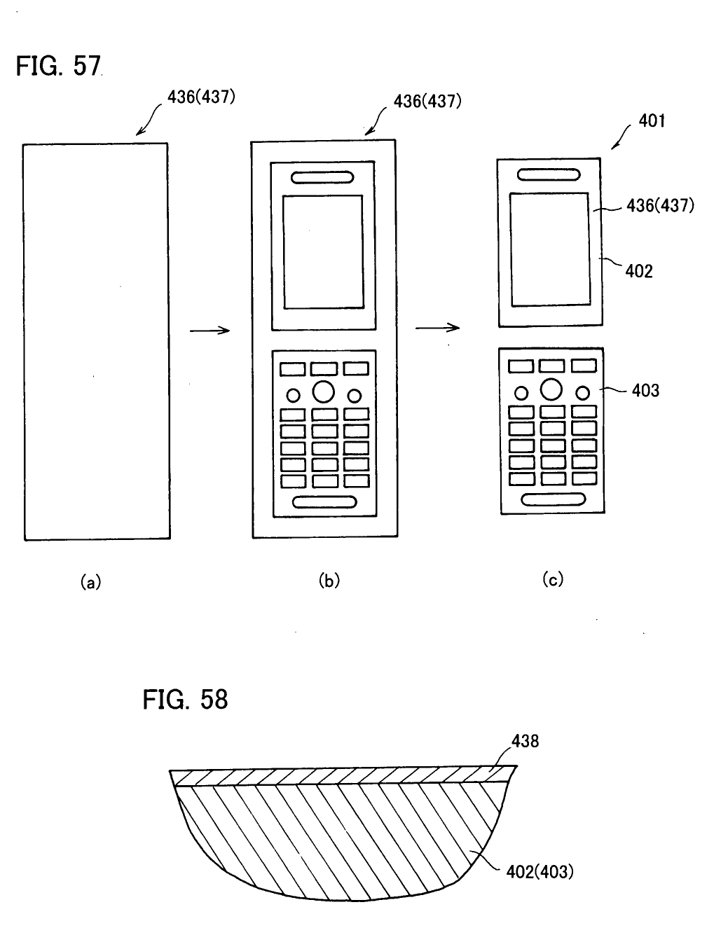

FIGS. 55A and 55B each are a cross sectional view of a sheet to be applied to the mobile phone handset so that the metal layer is laminated on the handset. FIGS. 56A and 56B each are a cross sectional view of a backed sheet (i.e., a sheet including a removable paper layer) from which the sheet in FIG. 55A or 55B is made. FIG. 57 is a schematic diagram showing procedures (a) to (c) of preliminary processing performed on a laminated sheet.

The sheet 420 applied to the surface of the handset 401 is formed, as shown in FIG. 55A, for example, by lamination of a metal layer 421 such as an aluminum foil in a middle part of the sheet 420, a resin layer 422 as a protection layer formed on an upper surface of the metal layer 421, and an adhesion layer 423 formed on an undersurface of the metal layer 421.

A more preferable sheet 426, as shown in FIG. 55B, for example, is formed by lamination of two aluminum layers 430 and 431 in a middle part of the sheet 426, a resin layer 422 as a protection layer formed at the outermost layer and on top of the aluminum layer 430, and an adhesion layer 423 formed at the outermost layer and on bottom of the aluminum layer 431. The sheet 426 further includes a resin layer 432 between the aluminum layers 430 and 431.

The sheets 420 and 426 each may have a print such as a pattern, a picture, and a photo, though may be unfigured.

Next, a preferable method for laminating a metal layer on a mobile phone handset using a sheet will be described below.

The present embodiment, as shown in FIGS. 56A and 56B, uses a backed sheet 436 or 437 formed by lamination of a removable paper layer 433 on the adhesion layer 423 of the sheet 420 or 426 shown in FIGS. 55A and 55B. The backed sheet 436 or 437 is applied to an inner surface of each of the casings 402 and 403 of the mobile phone handset 401 after having being preliminary processed as shown in FIG. 57.

A known cutting machine is used for cutting an unprocessed backed sheet 436 or 437 as shown in FIG. 57 (a) after having preliminary stored a shape or positions of elements such as the display of the handset 401. The cutting machine makes cut lines in the backed sheet 436 or 437 based on the shape or an arrangement of the switches of the handset 401 as shown in FIG. 57 (b). Instead of the cutting machine, a seal printer may be used to simultaneously form cut lines and print a pattern. Herein, the seal printer is a device having functions of a printer and of a cutting machine, enabling a desired printing on the backed sheet 436 or 437 and simultaneously cutting the backed sheet 436 or 437 into a desired shape.

Then, as shown in FIG. 57 (c), cut portions are torn from the backed sheet 436 or 437. Thereafter, the removable paper layer 433 on the bottom is removed to expose the adhesion layer 423, and the processed backed sheet 436 or 437 is applied to the surface of the body of each of the casings 402 and 403.

Other method include, as shown in FIG. 58, deposition or thermal spraying of an aluminum layer on the surface of the body of each of the casings 402 and 403 so as to attach a metal layer 438 to the surface.

FIG. 58 is a cross sectional view showing a surface stricture of a modified embodiment of the mobile phone handset of the present invention.

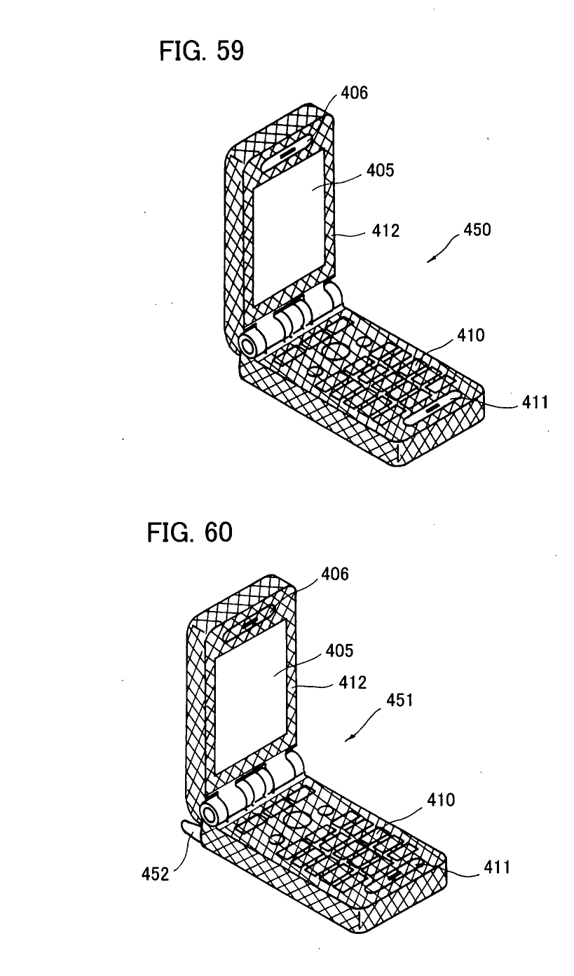

FIGS. 59 and 60 each are a perspective view of another modified embodiment of the mobile phone handset of the present invention.

The embodiments described above illustrate a structure in which a metal layer is attached to only a side (inner side), which is to be in contact with one's ear, of a twofold mobile phone handset. This structure allows the metal layer to be hidden inside of the handset when carrying it, so that the metal layer is unnoticeable. Therefore, this structure is recommended in view of looking nice. However, the present invention is not limited to this structure and may have a metal layer attached to the entire surface of a mobile phone handset 450 shown in FIG. 59, for example. The handset 450 shown in FIG. 59 has the metal layer attached to the entire surface except a display (viewing area) 405. In the handset 450 shown in FIG. 59, the metal layer is attached to also a receiver 406, operating switches 410, and a microphone 411.

Further, in the case of a structure in which an antenna 452 is exposed outside like a mobile phone handset 451 shown in FIG. 60, a metal layer may be attached to the entire surface except the antenna 452. The mobile phone handset 451 has the metal layer attached to the entire surface except a display (viewing area) 405 and the antenna 452. In the handset 451, the metal layer is attached to also a receiver 406, operating switches 410, and a microphone 411.

The mobile phone handsets 401, 450, and 451 in the embodiments described above each are used by a method similar to the known mobile phone handsets. As well as the known handsets, the handsets 401, 450, and 451 emit electromagnetic wave, but the metal layer is attached to a side to be in contact with one's head, thereby reducing the electromagnetic wave radiated to the head. Consequently, the long use of the mobile phone handsets 401, 450, and 451 has no concerns about damage of one's health.

1. A protection film for preventing leakage of information, comprising at least one metal layer and at least one resin layer laminated on each other.

2. The protection film as defined in claim 1,
the metal layer being an aluminum layer.

3. The protection film as defined in claim 1, comprising a plurality of the metal layers.

4. The protection film as defined in claim 3,
the metal layers including at least an aluminum layer.

5. The protection film as defined in claim 1, comprising at least one carbon layer.

6. The protection film as defined in claim 1, comprising a plurality of carbon layers.

7. The protection film as defined in claim 1, having various kinds of metal layers.

8. The protection film as defined in claim 1, comprising an aluminum layer and an iron layer.

9. The protection film as defined in claim 1, comprising an aluminum layer and a silver layer.

10. The protection film as defined in claim 1, comprising a copper layer.

11. The protection film as defined in claim 1, having strength enough to be sewn.

12. A portable pouch attached with the protection film for preventing leakage of information as defined in claim 1.

13. The portable pouch as defined in claim 12,
being provided with a card insertion pocket adapted to hold a card with part of the card exposed outside of the pocket,
the card insertion pocket being attached with the protection film.

14. The portable pouch as defined in claim 12,
being provided with a card insertion pocket adapted to hold a card with part of the card exposed outside of the pocket,
the card insertion pocket being formed by an inner wall to face a main body of the pouch and an outer wall on the opposite side of the inner wall, and
the protection film being attached to at least the inner wall of the pocket.

15. The portable pouch as defined in claim 12,
being provided with a card insertion pocket formed by a first wall and a second wall,
the first wall being attached with the protection film, and
the second wall being permeable to electromagnetic wave.

16. The portable pouch as defined in claim 12,
being adapted to contain a card having an electromagnetic wave shielding layer at its one side.

17. The portable pouch as defined in claim 12, comprising a base material layer made of one selected from cloth and leather,
the protection film being sewn onto the back of the base material layer.

18. The portable pouch as defined in claim 12,
the protection film being attached to a whole area of the pouch.

19. A card case being made of the protection film for preventing leakage of information as defined in claim 1.

20. An information-leakage preventing plate incorporating the protection film for preventing leakage of information as defined in claim 1.

21. The protection film for preventing leakage of information as defined in claim 1, having an adhesion layer formed at least one side.

22. A card provided with an information storing medium,
having a laminated barrier adapted to shield or attenuate electromagnetic wave or magnetism.

23. A card provided with an information storing medium,
having a laminated barrier adapted to shield or attenuate electromagnetic wave or magnetism at one of both sides of the card, the sides sandwiching a part where the storing medium is disposed.

24. The card as defined in claim 22,
wherein the storing medium is an IC chip.

25. The card as defined in claim 22,
wherein the storing medium is a magnetic storing medium.

26. The card as defined in claim 22,
wherein the barrier is a metal layer.

27. The card as defined in claim 22,
wherein the barrier is a laminated body comprising a metal layer and a resin layer.

28. A supplementary element for a card to be attached to one side of a card provided with an information storing medium,
having a function of shielding or attenuating electromagnetic wave or magnetism.

29. A skimming preventing card,
being adapted to shield electromagnetic wave or magnetism, and
having a printable surface.

30. A skimming preventing card,
being adapted to shield electromagnetic wave or magnetism, and
having an advertisement printed on its surface.

31. A method for advertising, comprising the steps of:
printing of an advertisement on a skimming preventing card adapted to shield electromagnetic wave or magnetism, and
distributing of the card free of charge or with charge.

32. A card printer, comprising:
a card containing section;
a photo shooting section;
a printing section adapted to print a photo shot in the photo shooting section on a card; and
a card ejecting section for ejecting the printed card,
wherein the card containing section contains skimming preventing cards adapted to shield electromagnetic wave or magnetism and to be printed on their surfaces.

33. A clothing having a part using at least one selected from (1) a film composed of lamination of a metal layer and (2) a resin layer and electromagnetic wave shielding cloth into which metallic yarn is woven.

34. The clothing as defined in claim 33,
the metal layer being an aluminum foil layer.

35. The clothing as defined in claim 33,
wherein the film has a plurality of metal layers.

36. The clothing as defined in claim 35,
at least one of the metal layers being an aluminum layer.

37. The clothing as defined in claim 33,
wherein the film has at least one carbon layer.

38. The clothing as defined in claim 33,
wherein the film has a plurality of carbon layers.

39. The clothing as defined in claim 33,
wherein the film has various kinds of metal layers.

40. The clothing as defined in claim 33,
wherein the film has strength enough to be sewn.

41. The clothing as defined in claim 33,
being underwear.

42. The clothing as defined in claim 33,
at least one selected from the film and the electromagnetic wave shielding cloth being arranged at a portion corresponding to testes.

43. The clothing as defined in claim 33,
at least one selected from the film and the electromagnetic wave shielding cloth being arranged at a portion corresponding to ovaries.

44. The clothing as defined in claim 33,
having a lining, and
at least part of the lining using at least one selected from the film and the electromagnetic wave shielding cloth.

45. The clothing as defined in claim 33,
having a pocket, and
at least part of the pocket using at least one selected from the film and the electromagnetic wave shielding cloth.

46. The clothing as defined in claim 33,
having a pocket, and
at least one selected from the film and the electromagnetic wave shielding cloth being arranged at a portion of the pocket to face a human body.

47. The clothing as defined in claim 33,
wherein the metallic yarn contains one selected from aluminum and silver.

48. The clothing as defined in claim 33,
wherein the cloth is woven by yarn, and
wherein the metallic yarn makes up 10 to 50% of the total number of the yarn woven into the cloth.

49. The clothing as defined in claim 33,
at least one selected from the film and the electromagnetic field shielding cloth being arranged at a portion corresponding to a position of a cardiac pacemaker.

50. A mobile phone handset, comprising:
a package containing integration of a microphone part for catching sound and a receiving part to be in contact with one's ear, and
having a metal layer arranged at least the part to be in contact with one's ear.

51. The mobile phone handset as defined in claim 50,
wherein the metal layer is formed by applying a metal foil onto a surface of the package of the handset.

52. The mobile phone handset as defined in claim 50,
wherein the metal layer is formed by spraying a metal onto a surface of the package of the handset.

53. The mobile phone handset as defined in claim 50,
wherein the metal layer is formed by depositing a metal onto a surface of the package of the handset.

54. The mobile phone handset as defined in claim 50,
wherein the metal layer is an aluminum layer.

55. The mobile phone handset as defined in claim 50,
wherein the metal layer has a thickness of 8 micrometer or more.

56. The mobile phone handset as defined in claim 50,
having a plurality of the metal layers.

57. The mobile phone handset as defined in claim 50,
being foldable, so that the receiving part is inwardly folded when carried.

58. The mobile phone handset as defined in claim 50,
further comprising a display,
wherein the metal layer is arranged over an entire surface of the package except the display.

59. The mobile phone handset as defined in claim 58,
further comprising an antenna projecting from the surface of the package,
wherein the metal layer is not arranged at part of or a front part of the antenna.
